(19) United States
(12) Patent Application Publication
(10) Pub. No.: US 2024/0421031 A1
(43) Pub. Date: Dec. 19, 2024

(54) ELECTRONIC DEVICE AND MANUFACTURING METHOD THEREOF

(71) Applicant: InnoLux Corporation, Miao-Li County (TW)

(72) Inventors: Te-Hsun LIN, Miao-Li County (TW); Wen-Hsuan CHANG, Miao-Li County (TW); Wen-Hsiang LIAO, Miao-Li County (TW)

(73) Assignee: InnoLux Corporation, Miao-Li County (TW)

(21) Appl. No.: 18/661,684

(22) Filed: May 12, 2024

Related U.S. Application Data
(60) Provisional application No. 63/472,599, filed on Jun. 13, 2023.

(30) Foreign Application Priority Data
Feb. 29, 2024 (CN) 202410224266.8

(51) Int. Cl. H01L 23/373; H01L 21/48; H01L 23/498; H01L 25/18

(52) U.S. Cl. CPC H01L 23/3736; H01L 21/4857; H01L 23/3731; H01L 23/49822; H01L 25/18

(57) ABSTRACT

An electronic device and a manufacturing method thereof are provided in the present disclosure. The electronic device includes a circuit structure, a plurality of electronic components and a structural unit. The circuit structure includes a plurality of conductive layers and at least one insulating layer. The plurality of conductive layers are electrically interconnected via a plurality of through holes in the at least one insulating layer. The plurality of electronic components are electrically connected to the circuit structure and are overlapped with the circuit structure. The structural unit is disposed adjacent to the plurality of electronic components. In a top view of the electronic device, at least a portion of the structural unit is disposed between adjacent two of the electronic components.

### CROSS REFERENCE TO RELATED APPLICATION

This application claims the benefit of U.S. Provisional Application No. 63/472,599, filed on Jun. 13, 2023. The content of the application is incorporated herein by reference.

### BACKGROUND OF THE DISCLOSURE

### 1. Field of the Disclosure

The present disclosure relates to an electronic device and a manufacturing method thereof, and more particularly to a packaged electronic device and a manufacturing method thereof.

### 2. Description of the Prior Art

In the technology of panel level package (PLP), carriers and circuit structures disposed thereon often suffer from warpage. If the warpage degree is too large, subsequent manufacturing processes would be adversely affected. For example, a solder ball mounting process might not be carried out normally or an electronic component bonding process might not be carried out normally, or circuit lines might be damaged due to excessive stress. As such, yield or reliability would be lowered. Therefore, how to solve the problem of warpage has been a technical issue to be solved so far.

### SUMMARY OF THE DISCLOSURE

It is an object of the present disclosure to provide an electronic device and a manufacturing method thereof.

An embodiment of the present disclosure provides a manufacturing method of an electronic device, which includes steps of: providing a carrier; disposing a circuit structure on the carrier, which includes alternately disposing a plurality of conductive layers and a plurality of insulating layers on the carrier, and electrically connecting adjacent two of the plurality of conductive layers via a plurality of through holes in one of the plurality of insulating layers; and disposing a structural unit at a side of the circuit structure. The structural unit has a first thermal expansion coefficient, one of the plurality of conductive layers of the circuit structure has a second thermal expansion coefficient, and a ratio of the first thermal expansion coefficient to the second thermal expansion coefficient is greater than or equal to 1.2 and less than or equal to 2.

Another embodiment of the present disclosure provides a manufacturing method of an electronic device, which includes steps of: providing a carrier; and disposing a circuit structure and a structural unit on the carrier, wherein the structural unit is disposed in the circuit structure, and disposing the circuit structure includes alternately disposing a plurality of conductive layers and a plurality of insulating layers on the carrier, and electrically connecting adjacent two of the plurality of conductive layers via a plurality of through holes in one of the plurality of insulating layers. The structural unit has a first thermal expansion coefficient, one of the plurality of conductive layers of the circuit structure has a second thermal expansion coefficient, and a ratio of the first thermal expansion coefficient to the second thermal expansion coefficient is greater than or equal to 0.1 and less than or equal to 0.8.

A further embodiment of the present disclosure provides an electronic device, which includes a circuit structure, a plurality of electronic components and a structural unit. The circuit structure includes a plurality of conductive layers and at least one insulating layer, wherein the plurality of conductive layers are electrically interconnected via a plurality of through holes in the at least one insulating layer. The electronic components are electrically connected to the circuit structure and overlapping the circuit structure. The structural unit is disposed adjacent to the plurality of electronic components, wherein in a top view of the electronic device, at least a portion of the structural unit is disposed between adjacent two of the plurality of electronic components.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 to FIG. 3 are schematic diagrams illustrating a manufacturing method of an electronic device according to a first embodiment of the present disclosure.

FIG. 4 is a flowchart schematically illustrating the manufacturing method of the electronic device in the first embodiment.

FIG. 5 to FIG. 7 are schematic diagrams illustrating a manufacturing method of an electronic device according to a second embodiment of the present disclosure.

FIG. 8 to FIG. 10 are schematic diagrams illustrating a manufacturing method of an electronic device according to a third embodiment of the present disclosure.

FIG. 11 is a flowchart schematically illustrating the manufacturing method of the electronic device in the third embodiment.

FIG. 12 to FIG. 14 are schematic diagrams illustrating a manufacturing method of an electronic device according to a fourth embodiment of the present disclosure.

FIG. 15 is a schematic diagram illustrating a structure formed before a cutting process of a manufacturing method of an electronic device according to a fifth embodiment of the present disclosure.

FIG. 16 is a top view schematically illustrating a structural unit and electronic components disposed on a carrier according to a sixth embodiment of the present disclosure.

FIG. 17 is a top view schematically illustrating a structural unit and electronic components disposed on a carrier according to a seventh embodiment of the present disclosure.

FIG. 18 is a top view schematically illustrating a structural unit and electronic components disposed on a carrier according to an eighth embodiment of the present disclosure.

FIG. 19 is a top view schematically illustrating a structural unit and electronic components of an electronic device according to a ninth embodiment of the present disclosure.

FIG. 20 is a cross-sectional view schematically illustrating the electronic device in the ninth embodiment.

FIG. 21 is a top view schematically illustrating a structural unit and electronic components of an electronic device according to a tenth embodiment of the present disclosure.

FIG. 22 is a cross-sectional view schematically illustrating the electronic device in the tenth embodiment.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams of electronic devices or a portion of the electronic devices, and components therein may not be drawn to scale. The numbers and dimensions of the components in the drawings are just illustrative, and are not intended to limit the scope of the present disclosure.

Certain terms are used throughout the specification and the appended claims of the present disclosure to refer to specific components. Those skilled in the art should understand that electronic equipment manufacturers may refer to a component by different names, and this disclosure does not intend to distinguish between components that differ in name but not function. The following description exemplifies several embodiments in the present disclosure to introduce the principal concepts of the present disclosure, and is not intended to limit the contents of the present disclosure. The actual scope of the disclosure is defined based on claims. Reference will now be made in detail to exemplary embodiments of the present disclosure, and examples are illustrated in the accompanying drawings. Wherever possible, the same element symbols are used in the drawings and description to indicate the same or similar parts.

The directional terms referred to in the present disclosure, e.g. “up”, “down”, “front”, “back”, “left”, “right”, etc., are only directions with reference to the accompanying drawings. Accordingly, the directional terms used are for illustrative purposes and are not intended to limit the scope. In the accompanying drawings, each of the accompanying drawings illustrates the general features of the methods, structures and/or materials used in a particular embodiment. However, the accompanying drawings should not be construed as defining or limiting the scope or nature of what is covered by these embodiments. For example, the relative size, thickness and position of a film, a layer, a region and/or a structure may be reduced or enlarged for clarity. The present disclosure can be understood by reference to the following detailed description and in conjunction with the accompanying drawings. It should be noted that, in order to enable the reader to easily understand and for the sake of simplicity of the accompanying drawings, some of the accompanying drawings of the present disclosure only illustrate a portion of an electronic device, and specific elements in the accompanying drawings are not drawn in accordance with actual proportions. In addition, the number and size of the elements in the drawings are for illustrative purposes only and are not intended to limit the scope of the present disclosure.

In the following description and claims, the terms “comprise”, “include” and “have” are used in an open-ended fashion, thus they should be interpreted as “including but not limited to . . . ”.

It should be understood that when a component or layer is referred to as being “on” or “disposed on” another component or layer, or “connected to” another component or layer, it may be directly on the component or layer or directly connected to the component or layer, or there may be an interposed component or layer between the two components or layers (indirect case). Conversely, when a component is referred to as being “directly on” another component or layer, “directly disposed on” another component or layer, or “directly connected to” another component or layer, there are no interposed components or layers between the two components or layers.

In some embodiments of the present disclosure, terms such as “connection”, “interconnection”, etc., with respect to joining, connecting, etc., unless specifically defined, may refer to two structures being in direct contact, or may also refer to two structures that are not in direct contact but interposed therebetween some other structures. The terms “joint” and “connection” may also include cases where both structures are movable or both structures are fixed. In addition, the terms “electrically connected” or “electrically coupled” include any method of direct and indirect electrical connection.

In addition, it should be understood that although the terms “first”, “second”, “third”, etc. may be used herein to describe various components, these components should not be limited by these terms. These terms may be used to distinguish different components in the specification. The same terms may not be used in the claims, and the components in the claims may be described by the terms “first”, “second”, “third”, etc. according to the order of the components presented in the claims. Thus, a first component discussed below may be termed as a second component in the claims without departing from the present disclosure.

In the specification of the present disclosure, roughness is defined as the peaks and valleys of surface undulations that can be seen on the surface of a given element with a distance difference of 0.15 micrometers to 0.5 micrometers when viewed with a scanning electron microscope (SEM). Roughness measurements may include the use of a scanning electron microscope, transmission electron microscope (TEM), etc., to observe the surface undulation at the same appropriate magnification. In addition, a unit length (e.g., 10 microns) is sampled to determine a condition of ups and downs. In this disclosure, “appropriate magnification” means that at least one surface can be seen with at least 10 undulating spikes in the field of view at this magnification. The distances between the aforementioned elements can be measured, for example, on a sectional view by means of a ruler of a scanning electron microscope.

It should be understood that according to the following embodiments, features of different embodiments may be replaced, recombined or mixed to constitute other embodiments without departing from the spirit of the present disclosure.

Here, the terms “about”, “equal to”, “equal” or “the same”, “substantially” or “approximately” usually mean within 20% of a given value, or within 108, 58, 3%, 28, 1% or 0.5% of the given value. In the present disclosure, the expressions “the given range is from the first value to the second value” and “the given range falls within the range from the first value to the second value” indicate that the given range includes the first value, the second value and other values in between.

Further, there may be a margin of error between any two values or directions used for comparison. If the first value is equal to the second value, it is implied that there may be an error of about 10% between the first value and the second value; if the first direction is perpendicular or “substantially” perpendicular to the second direction, the angle between the first direction and the second direction may be between 80 and 100 degrees; if the first direction is parallel or “substantially” parallel to the second direction, the angle between the first direction and the second direction may be between 0 degrees and 10 degrees.

The electronic devices of the present disclosure may be used in a power module, a semiconductor package device, a display device, a lighting device, a backlight device, an antenna device, a sensing device or a tiled electronic device, but not limited thereto. In the present disclosure, the electronic devices may include a variety of electronic components, for example, a semiconductor package component, a display device, a lighting element, a sensing element, an antenna element, a bendable electronic device, a tiled electronic device or a flexible electronic device, but not limited thereto.

The electronic device may include a semiconductor die or a stack layer formed by alternately stacking multiple metal layers (e.g., copper layers and crystal seed layers) and multiple insulating layers, such as a redistribution layer (RDL), but not limited thereto. The term “flexible/bendable” used herein refers to a material that can be curved, bent, folded, rolled, flexed, stretched and/or similarly deformed to represent at least one of the above possible deformations. Being “flexible/bendable” is not limited to the aforementioned deformations.

The antenna device may be a liquid crystal antenna or a non-liquid-crystal antenna, the sensing element may be a sensor sensing capacitance, light, thermal energy or supersonic waves, but not limited thereto.

The electronic component may include a passive component, an active component, or a combination of the foregoing, such as a capacitor, a resistor, an inductor, a varactor diode, a variable capacitor, a filter, a diode, a transistor, a sensor, a microelectromechanical system component (MEMS), a liquid crystal chip, and so forth, but not limited thereto. The diode may include a light emitting diode or a non-light emitting diode. The diode may include a P-N junction diode, a PIN type diode or a constant current diode. The light-emitting diode may include, for example, an organic light emitting diode (OLED), a mini light emitting diode (mini LED), a micro light emitting diode (micro LED), a quantum-dot light emitting diode (quantum-dot LED), a fluorescent light emitting diode, a phosphor light emitting diode or any other suitable light emitting diode, or any combination thereof, but not limited thereto.

The sensing element may, for example, include a capacitive sensor, an optical sensor, an electromagnetic sensor, a fingerprint sensor, a touch sensor, an antenna or a stylus pen, but not limited thereto.

The electronic component may include a die or a light emitting diode die (LED die), which may be made of silicon (Si), gallium arsenide (GaAs), gallium nitride (GaN), silicon carbide (Sic), sapphire or glass substrate, but not limited thereto. In one embodiment, the die includes a semiconductor package element, such as, but not limited to, a Ball Grid Array (BGA) package element, a Chip Size Package (CSP) element, a flip chip, or a 2.5-dimensional/3-dimensional (2.5D/3D) semiconductor package element. In another embodiment, the die may be any kind of flip chip bonding element, such as, but not limited to, an integrated circuit (IC), a transistor, a silicon controlled rectifier (SCR), a valves, a thin-film transistor (TFT), a capacitor, an inductor, a variable capacitor, a filter, a resistor, a diode, a microelectromechanical system component (MEMS), a liquid crystal die, and the like. The die includes, for example, a diode or a semiconductor die, but not limited thereto. The die may be a known good die (KGD), which may include various electronic components, such as (but not limited to) wires, transistors, circuit boards, and the like. Neighboring dies may have different functions from each other, such as integrated circuits, RFICs, D-RAMs, but not limited thereto.

If the electronic device is applied in packaging, it can be applied to panel level packaging (PLP), ball grid array packaging (BGA), chip scale packaging (CSP), chip on wafer on substrate (CoWoS) and any other suitable packaging method, such as chip-first or redistribution layer first (RDL first), but not limited thereto.

It should be noted that the electronic components may be any combination of the foregoing components, but not limited thereto. Each embodiment of the present disclosure illustrates a combination of plural electronic components packaged in packaging material, redistribution structures, metal layers, insulating layers, end shafts, bonding elements and input/output bonding pads (I/O pads). The electronic components of the present disclosure are exemplified to be fan-out packaged electronic components, but not limited thereto.

The contents of the present disclosure will be illustrated hereinafter with an electronic device exemplified by a packaging device, but not limited thereto. The dielectric material in the redistribution layer may include, but is not limited to, an organic dielectric material, an inorganic dielectric material, or a combination of the foregoing dielectric materials that can be used for packaging. The organic dielectric material may include, for example, polybenzoxazole (PBO), benzocyclobutene (BCB), acrylic, ABF carrier, polyimide (PI), polyamide, any other suitable material or a combination of the foregoing, which can be used for pakaging, but not limited thereto. The inorganic dielectric material may include, for example, silicon oxide, silicon nitride, alumina, siloxane, any other suitable material or a combination of the foregoing, which can be used for packaging, but not limited thereto.

The following accompanying drawings identify Direction V, Direction X and Direction Y. Direction V may be a top view direction or a direction perpendicular to a surface 100S of a carrier 100, and Direction X and Direction Y may be directions parallel to the surface 100S of the carrier 100. Direction X and Direction Y may be perpendicular to Direction V. The following accompanying drawings may depict the spatial relationship of the structure based on Direction V, Direction X and Direction Y.

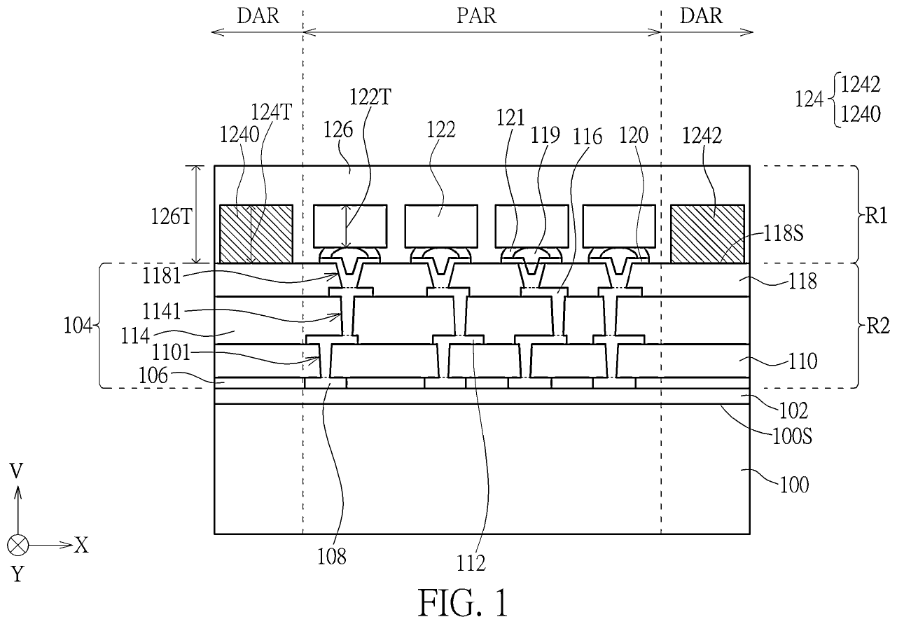

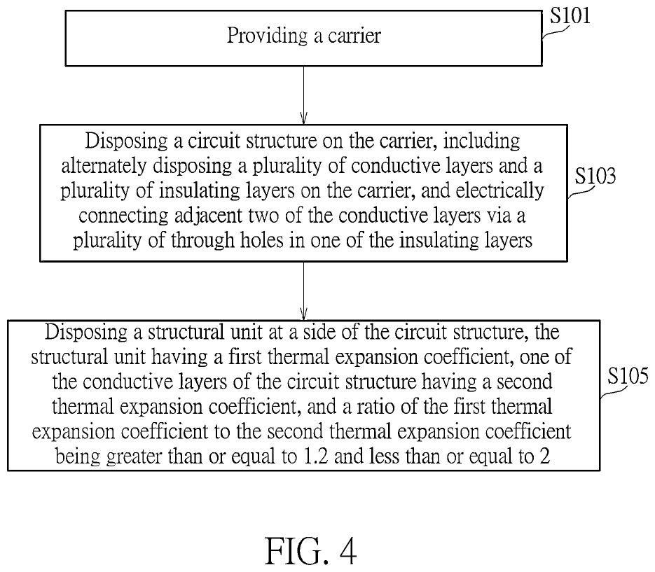

Please refer to FIG. 1 to FIG. 4. FIG. 1 to FIG. 3 are schematic diagrams illustrating a manufacturing method of an electronic device according to a first embodiment of the present disclosure. FIG. 4 is a flowchart schematically illustrating the manufacturing method of the electronic device in the first embodiment. It is to be noted that the steps illustrated in FIG. 4 may not be exhaustive, and additional steps may be performed before, after, or between any of the existing steps. In addition, some of the steps may be performed simultaneously or in a different order other than that shown in FIG. 4.

First of all, a carrier 100 is provided in Step S101. The material of the carrier used in the present disclosure may include a supportive substrate, such as a substrate of an organic or inorganic material, which may include a glass substrate, a ceramic substrate, a plastic substrate, a copper substrate, a steel plate, a polyimide (PI) substrate, a polyethylene terephthalate (PET) substrate, a wafer, any other suitable material or a combination of the foregoing. The shape of the substrate 110 in the top view may include a rectangle, a square, a circle, a polygon, or a free shape, but not limited thereto.

Subsequently, a release layer 102 may be formed on the carrier 100. The adhesion of the release layer 102 may be adjusted, for example, by irradiating with a particular light or heating, thereby facilitating peeling of a circuit structure 104 from the carrier 100, but it is not limited thereto. The “release layer” as described in the present disclosure may include an adhesive material, including, but not limited to, an adhesive material that can be separated by laser, light or thermal cracking. In some embodiments (not shown), an anti-warping layer (not shown) may optionally be incorporated between the release layer 102 and the carrier 100.

Subsequently, a circuit structure 104 is disposed on the carrier 100 in Step 103. The circuit structure 104 may be, but not limited to, a redistribution layer (RDL). For example, a plurality of conductive layers and a plurality of insulating layers may be alternately disposed on the carrier 100, and adjacent two of the plurality of conductive layers may be electrically connected via a plurality of through holes in one of the plurality of insulating layers. As shown in FIG. 1, regarding “alternately disposing a plurality of conductive layers and a plurality of insulating layers”, the circuit structure 104 may include, for example, an insulating layer 106, a conductive layer 108, an insulating layer 110, a conductive layer 112, an insulating layer 114, a conductive layer 116, an insulating layer 118 and a conductive layer 120, which are sequentially formed, but not limited thereto.

The circuit structure 104 may be used as the redistribution layer (RDL). The circuit structure 104 may be electrically connected to the electronic components via bonding pads, and may include at least one conductive layer and at least one insulating layer. The circuit structure 104 may, for example, increase the fan-out area of signal lines, or different electronic components may be electrically connected to each other via the circuit structure 104.

For example, the insulating layer 106 is first formed on the release layer 102, a plurality of openings are formed in the insulating layer 106, and then the conductive layer 108 is formed, filling the openings in the insulating layer 106. The conductive layer 108 may include a plurality of contact pads. Next, the insulating layer 110 is formed on the insulating layer 106 and the conductive layer 108, and a plurality of through holes 1101 are formed in the insulating layer 110. The conductive layer 112 is formed on the insulating layer 110 and portions of the conductive layer 112 are disposed in the through holes 1101. The above steps are then repeated to sequentially form the insulating layer 114, a plurality of through holes 1141 in the insulating layer 114, the conductive layer 116, the insulating layer 118, a plurality of through holes 1181 in the insulating layer 118, and the conductive layer 120, but not limited thereto. The number of the conductive layers and the number of the insulating layers may be adjusted according to demands, and the order of the above process is only an example, which may be modified according to demands. The process for forming the circuit structure 104 is not limited to the manufacturing method described above.

The insulating layers in the circuit structure 104 may include an organic material or an inorganic material, e.g., photosensitive polyimide (PSPI), polyethylene (PE), polyethylene terephthalate (PET), polycarbonate (PC), polytetrafluoroethylene (PTFE), polystyrene (PS), acrylonitrile butadiene styrene (ABS), any other suitable material, or any combination thereof, but not limited thereto. In some embodiments, the insulating layers in the circuit structure 104 described above may include, for example (but not limited to), polyimide, epoxy, silicon nitride (SiNx), silicon oxide (SiOx), or a combination of the foregoing.

Any of the conductive layers included in the circuit structure 104 may include a seed layer and/or a metal material layer. The seed layer includes, for example, but not limited to, titanium, copper or nickel. The conductive layer may include a single layer or multiple stacked layers, for example, including copper (Cu), aluminum (Al), molybdenum (Mo), tungsten (W), gold (Au), chromium (Cr), nickel (Ni), platinum (Pt), titanium (Ti), silver (Ag), tantalum (Ta), any other suitable metal material, or any combination of the foregoing. In some embodiments, as shown in FIG. 1, the conductive layer 120 may include an under bump metallization (UBM) layer, but is not limited thereto.

Subsequently, a structural unit 124 is disposed at a side of the circuit structure 104 in Step S105. In some embodiments, a plurality of electronic components 122 and/or the structural unit 124 are disposed after the circuit structure 104 is disposed. The electronic components 122 and the structural unit 124 are disposed on the circuit structure 104 at a side, e.g., the upper side, but not limited thereto. The electronic components 122 and the structural unit 124 may be disposed on the insulating layer 118. The electronic components 122 and the structural unit 124 are at least partially overlapped in a direction parallel to a surface 100S of the carrier 100. The electronic components 122 may be electrically connected to the conductive layer 120 through a plurality of connecting conductive members 119, but not limited thereto. Insulating layers 121 may be formed around the connecting conductive members 119, overlying the connecting conductive members 119. The insulating layer 121 may be used to protect the connecting conductive members 119 and/or to improve the bonding yield of the electronic components 122. In some embodiments (not shown), the insulating layer 121 may selectively contact the side surface of the electronic component 122.

As shown FIG. 1, the electronic components 122 are defined as being disposed in a first region R1 in the cross-sectional structure, and the circuit structure 104 is defined as being disposed in a second region R2 in the cross-sectional structure. In the embodiment as illustrated in FIG. 1, the circuit structure 104 is disposed between the electronic components 122 and the carrier 100. A boundary between the first region R1 and the second region R2 may be defined by, for example, an upper surface (e.g., an upper surface 118S) of the topmost insulating layer (e.g., the insulating layer 118), but not limited thereto. In some embodiments, the structural unit 124 may be disposed in the first region R1, but not limited thereto.

In a cross-sectional diagram as shown in FIG. 1, the electronic components 122 and the structural unit 124 are at least partially overlapped in a direction (e.g., Direction X or Direction Y) parallel to a surface 100S of the carrier 100, and the electronic components 122 and the structural unit 124 are not overlapped in a direction (e.g., Direction V) perpendicular to the surface 100S of the carrier 100. The structural unit 124 and a portion of the conductive layer 120 may be disposed on, for example, the upper surface 118S of the insulating layer 118 and substantially coplanar, but not limited thereto. In some embodiments, the structural unit 124 and the portion of the conductive layer 120, which is disposed on the upper surface 118S of the insulating layer 118, may not be co-planar. In a cross-sectional diagram as shown in FIG. 1, the structural unit 124 may be at least partially overlapped with the portion of the conductive layer 120, the connecting conductive members 119, the insulating layer 121 and/or the electronic components 122 in the direction parallel to the surface 100S of the carrier 100, e.g., Direction X or Direction Y, but not limited thereto.

In this embodiment, the structural unit 124 illustrated in the cross-sectional diagram has a maximum thickness 124T, and the maximum thickness 124T is greater than or equal to a maximum thickness 122T of the electronic component 122, but not limited thereto. In some embodiments, the maximum thickness 124T of the structural unit 124 illustrated in the cross-sectional diagram may not be equal to the maximum thickness 122T of the electronic component 122. In some embodiments and in the cross-sectional diagram, a ratio of a maximum thickness 126T of an encapsulation layer 126 to the maximum thickness 124T of the structural unit 124 may be greater than or equal to 1.5 and less than or equal to 6, or the ratio may be greater than or equal to 2 and less than or equal to 5, but not limited thereto. In some embodiments, the shape of the structural unit 124 illustrated in the cross-sectional diagram may be a rectangle, but not limited thereto. It may include other shapes, e.g., trapezoid, or it may include arc edges or an irregular shape according to requirements. In other embodiments, the maximum thickness 124T of the structural unit 124 may be less than the maximum thickness 122T of the electronic component 122.

The carrier 100 may include a package area PAR and a non-package area DAR. The non-package area DAR is at least disposed at a side of the package area PAR or surrounds the package area PAR. The electronic components 122 and/or the conductive layers of the circuit structure 104 may be disposed in the package area PAR, and the structural unit 124 may be disposed in the non-package area DAR, but not limited thereto. In other embodiments (not shown), the conductive layers of the circuit structure 104 may be selectively disposed in the non-package area DAR, and may be selectively in contact with the structural unit 124, but not limited thereto. As shown in FIG. 1, in some embodiments, in Direction X (or Direction Y), the electronic components 122 may be disposed between a portion 1240 and another portion 1242 of the structural unit 124, but not limited thereto.

The structural unit 124 has a first thermal expansion coefficient, one of the conductive layers of the circuit structure 104 (e.g., one of the conductive layer 108, the conductive layer 112, the conductive layer 116 and the conductive layer 120) has a second thermal expansion coefficient. The first thermal expansion coefficient is different from the second thermal expansion coefficient. For example, a ratio of the first thermal expansion coefficient to the second thermal expansion coefficient (i.e., the first thermal expansion coefficient/the second thermal expansion coefficient) is greater than or equal to 1.2 and less than or equal to 2. With such a designed ratio of the first thermal expansion coefficient to the second thermal expansion coefficient, a warping direction of the structure in the non-package area DAR may be, for example, opposite to a warping direction of the structure in the package area PAR, alleviating the warpage of the overall structure.

As shown in FIG. 1, when the structural unit 124 is disposed in the first region R1, or when the structural unit 124 is disposed at a side (e.g., the upper side) of the circuit structure 104 in Direction V (e.g., the direction perpendicular to the surface 100S of the carrier 100), or when the structural unit 124 is at least partially overlapped with the electronic components 122 in the direction parallel to the surface 100S of the carrier 100 (e.g., Direction X or Direction Y), a ratio of the first thermal expansion coefficient of the material of the structural unit 124 to the second thermal expansion coefficient of the material of one of the conductive layers of the circuit structure 104 (the first thermal expansion coefficient/the second thermal expansion coefficient) is greater than or equal to 1.2 and less than or equal to 2, but not limited thereto. The ratio may also be greater than or equal to 1.3 and less than or equal to 1.9, or greater than or equal to 1.4 and less than or equal to 1.8. When the material of the structural unit 124 and the material of one of the conductive layers of the circuit structure 104 meet the range of the ratio of thermal expansion coefficients, the warpage of the overall structure can be effectively suppressed so as to improve yield and reliability of the electronic device.

In some embodiments, the structural unit 124 may include copper, aluminum, copper alloy, any other suitable metal material with a high thermal expansion coefficient, or a combination of the foregoing, but not limited thereto. In some embodiments, the first thermal expansion coefficient of the structural unit 124 may be greater than or equal to 20.4 ppm/° C. and less than or equal to 34 ppm/° C., but not limited thereto. In some embodiments, the first thermal expansion coefficient of the structural unit 124 may be greater than or equal to 22 ppm/° C. and less than or equal to 32 ppm/° C., but not limited thereto. In some embodiments, the first thermal expansion coefficient of the structural unit 124 may be greater than or equal to 20 ppm/° C. and less than or equal to 30 ppm/° C., but not limited thereto.

Subsequently, an encapsulation layer 126 is formed on the electronic components 122, the structural unit 124 and the circuit structure 104. By way of disposing the encapsulation layer 126, the contact or penetration of moisture or oxygen into the corresponding elements can be reduced, thereby increasing the reliability of the elements or the stacked layers. According to some embodiments, the encapsulation layer 126 may include an organic resin, an epoxy resin, an epoxy molding compound (EMC), a ceramic, a poly(methyl methacrylate) (PMMA), a polydimethylsiloxane (PDMS), any other suitable material, or a combinations of the foregoing, but not limited thereto.

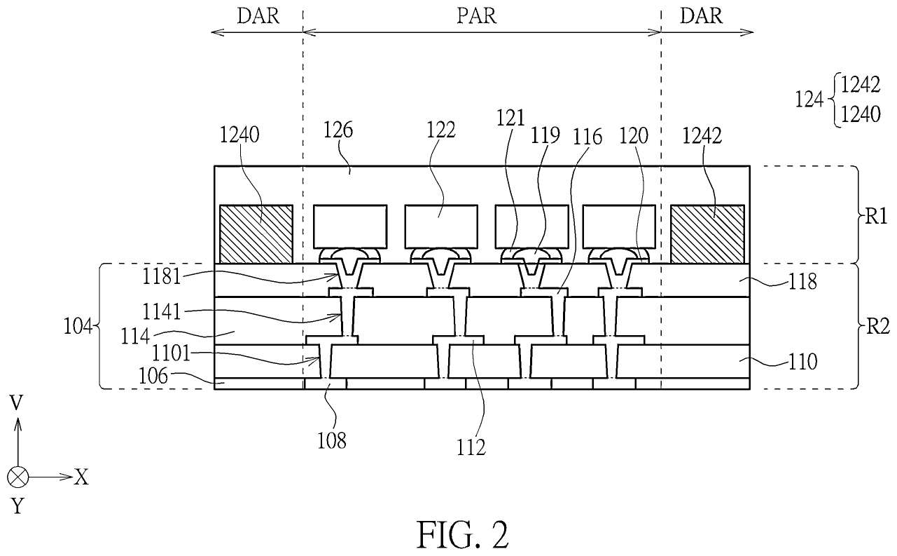

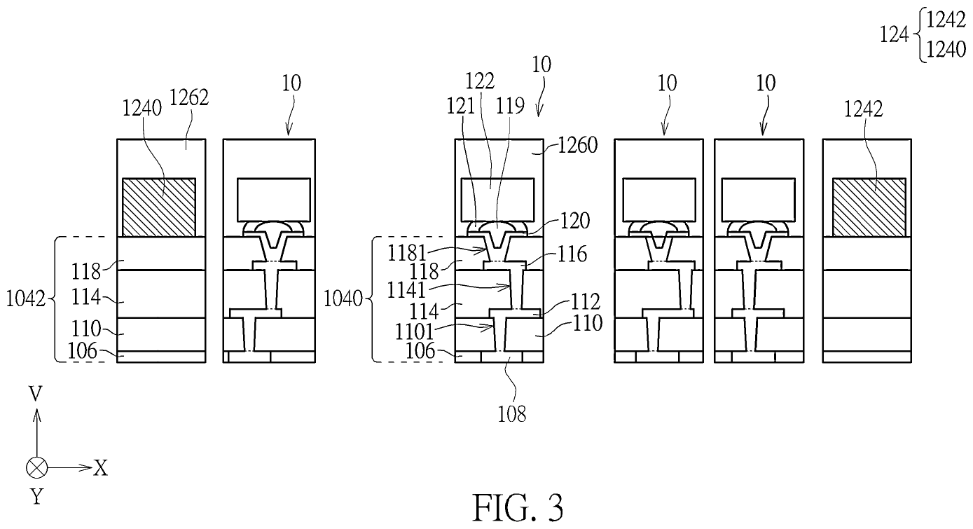

Subsequently, as shown in FIG. 2, the release layer 102 and the carrier 100 are removed. Then, as shown in FIG. 3, the electronic components 122 and the structural unit 124 can be separated from each other by a cutting process. The cutting process is performed along Direction V, and a plurality of electronic devices 10 are obtained after the cutting process. The cutting process may include a laser cutting process or any other suitable cutting process, but not limited thereto.

As shown in FIG. 3, each of the electronic devices 10 may include at least one electronic component 122, an encapsulation layer portion 1260 corresponding to the electronic component 122, and a circuit structure portion 1040 corresponding to the electronic component 122. The encapsulation layer portion 1260 is a portion of the encapsulation layer 126 shown in FIG. 2, and the circuit structure portion 1040 is a portion of the circuit structure 104 shown in FIG. 2, but not limited thereto. In an exemplary drawing of an embodiment analogous to the present disclosure, although the electronic component 122 of the electronic device 10 obtained by the cutting process is electrically connected to the circuit structure portion 1040 through only one connecting conductive member 119, the electronic component 122 of the electronic device 10 may actually be electrically connected to the circuit structure portion 1040 through more than one connecting conductive member 119.

Furthermore, the structural unit 124 (e.g., the portion 1240 and the portion 1242), an encapsulation layer portion 1262 corresponding to the structural unit 124 and a circuit structure portion 1042 corresponding to the structural unit 124 may be selectively removed. The encapsulation layer portion 1262 is a portion of the encapsulation layer 126 shown in FIG. 2, and the circuit structure portion 1042 is a portion of the circuit structure 104 shown in FIG. 2, but not limited thereto.

Therefore, in some embodiments, a manufacturing method of the electronic device 10 includes, but not limited to, the following steps:
S101: providing a carrier;
S103: disposing a circuit structure on the carrier, which includes alternately disposing a plurality of conductive layers and a plurality of insulating layers on the carrier, and electrically connecting adjacent two of the conductive layers via a plurality of through holes in one of the insulating layers; and
S105: disposing a structural unit at a side of the circuit structure, wherein the structural unit has a first thermal expansion coefficient, one of the conductive layers of the circuit structure has a second thermal expansion coefficient, and a ratio of the first thermal expansion coefficient to the second thermal expansion coefficient is greater than or equal to 1.2 and less than or equal to 2.

The electronic device and the manufacturing method thereof in the present disclosure are not limited to the above embodiments. Other embodiments of the present disclosure will be described below. However, in order to simplify the description and to highlight the differences between the embodiments, the same elements are labeled with the same numeral references in the present disclosure, and the repetitions will not be redundantly described.

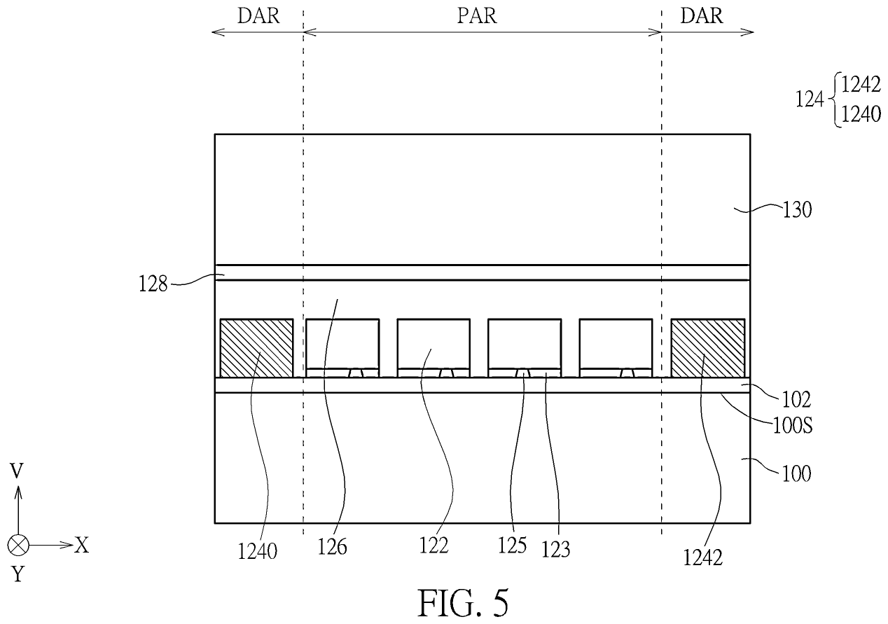

Please refer to FIG. 5 to FIG. 7, which are schematic diagrams illustrating a manufacturing method of an electronic device according to a second embodiment of the present disclosure. This embodiment differs from the first embodiment in that a plurality of electronic components 122 and a structural unit 124 are disposed before a circuit structure 104 is disposed. In this embodiment, as shown in FIG. 5, a carrier 100 is first provided and a release layer 102 is then formed on the carrier 100. Next, the electronic components 122 and the structural unit 124 are disposed on the release layer 102. The electronic components 122 and the structural unit 124 are at least partially overlapped in a direction (e.g., Direction X or Direction Y) parallel to a surface 100S of the carrier 100, and the electronic components 122 and the structural unit 124 are not overlapped in another direction (e.g., Direction V) perpendicular to the surface 100S of the carrier 100. A plurality of insulating structures 123 are disposed between the electronic components 122 and the release layer 102, or between the electronic components 122 and the carrier 100, respectively. The insulating structures 123 may be spaced from and not in contact with each other, and may be overlapped with different electronic components 122, but not limited thereto. The insulating structures 123 may include insulating materials, such as inorganic or organic insulating materials, but not limited thereto. In some embodiments, the insulating structures 123 may include ABF (Ajinomoto Build-Up Film) carrier, but not limited thereto. Subsequently, an encapsulation layer 126 is formed on the electronic components 122 and the structural unit 124, and the encapsulation layer 126 may cover the electronic components 122 and the structural unit 124. A release layer 128 and a carrier 130 are then sequentially formed on the encapsulation layer 126.

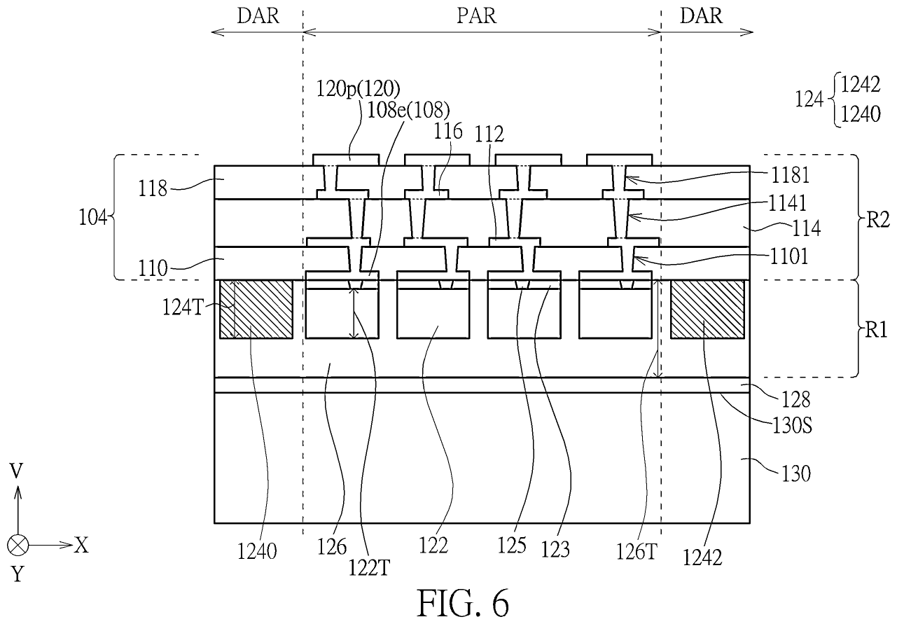

Subsequently, the structure shown in FIG. 5 is 180-degree flipped, and the release layer 102 and the carrier 100 are removed. Then, as shown in FIG. 6, the circuit structure 104 is formed on the electronic components 122 and the structural unit 124. For example, a conductive layer 108, an insulating layer 110, through holes 1101 in the insulating layer 110, a conductive layer 112, an insulating layer 114, through holes 1141 in the insulating layer 114, a conductive layer 116, an insulating layer 118, through holes 1181 in the insulating layer 118, and a conductive layer 120 are sequentially formed on the insulating structures 123 and the structural unit 124, but not limited thereto. The process of forming the circuit structure 104 may be referred to the process illustrated with reference to FIG. 1. In this embodiment that the insulating structures 123 are disposed between the circuit structure 104 and the electronic components 122, a boundary between the first region R1 and the second region R2 may be an interface between the insulating layer 110 and the insulating structures 123, but not limited thereto. The conductive layer 108 may include a plurality of electrodes 108e, and the electronic component 122 may be electrically connected to the electrode 108e of the conductive layer 108 via a connecting conductive member 125 formed in the insulating structure 123, but not limited thereto.

Furthermore, the conductive layer 120 may include a plurality of contact pads 120p, but not limited thereto. In Direction X (or Direction Y), a width of the contact pad 120p is greater than a width of the electrode 108e, and the contact pads 120p are partially overlapped with the electrodes 108e, but not limited thereto. In a cross-sectional diagram as shown in FIG. 6, the structural unit 124 is at least partially overlapped with a portion of the insulating structures 123, the connecting conductive members 125 and/or the electronic components 122 in a direction (e.g., Direction X or Direction Y) parallel to a surface 130S of the carrier 130, but not limited thereto.

In this embodiment and in the cross-sectional diagram, the structural unit 124 has a maximum thickness 124T, and the maximum thickness 124T is greater than or equal to a maximum thickness 122T of the electronic component 122, but not limited thereto. In some embodiments and in the cross-sectional diagram, the maximum thickness 124T of the structural unit 124 may not be equal to the maximum thickness 122T of the electronic components 122. In some embodiments and in the cross-sectional diagram, a ratio of the maximum thickness 126T of the encapsulation layer 126 to the maximum thickness 124T of the structural unit 124 may be greater than or equal to 1.5 and less than or equal to 6, or the ratio may be greater than or equal to 2 and less than or equal to 5, but not limited thereto. In further embodiments (not shown) and in the cross-sectional diagram, the maximum thickness 124T of the structural unit 124 may be less than the maximum thickness 122T of the electronic components 122. In some embodiments, the shape of the structural unit 124 illustrated in the cross-sectional diagram may include a rectangle, but not limited thereto. It may include other shapes, e.g., trapezoid, or it may include arc edges or an irregular shape according to requirements.

As shown in FIG. 6, when the structural unit 124 is disposed in the first region R1, or when the structural unit 124 is disposed at a side (e.g., a lower side) of the circuit structure 104 in the direction (e.g., Direction V) perpendicular to the surface 130S of the carrier 130, or when the structural unit 124 is at least partially overlapped with the electronic components 122 in the direction (e.g., Direction X or Direction Y) parallel to the surface 130S of the carrier 130, a ratio of the first thermal expansion coefficient of the material of the structural unit 124 to the second thermal expansion coefficient of the material of one of the conductive layers of the circuit structure 104 is greater than or equal to 1.2 and less than or equal to 2, but not limited thereto. The ratio may also be greater than or equal to 1.3 and less than or equal to 1.9, or greater than or equal to 1.4 and less than or equal to 1.8. When the material of the structural unit 124 and the material of one of the conductive layers of the circuit structure 104 meet the range of the ratio of thermal expansion coefficients, the warpage of the overall structure can be effectively suppressed so as to improve yield and reliability of the electronic device. The material of the structural unit 124 and the material of the conductive layers of the circuit structure 104 have been described in the first embodiment, and not to be redundantly described herein.

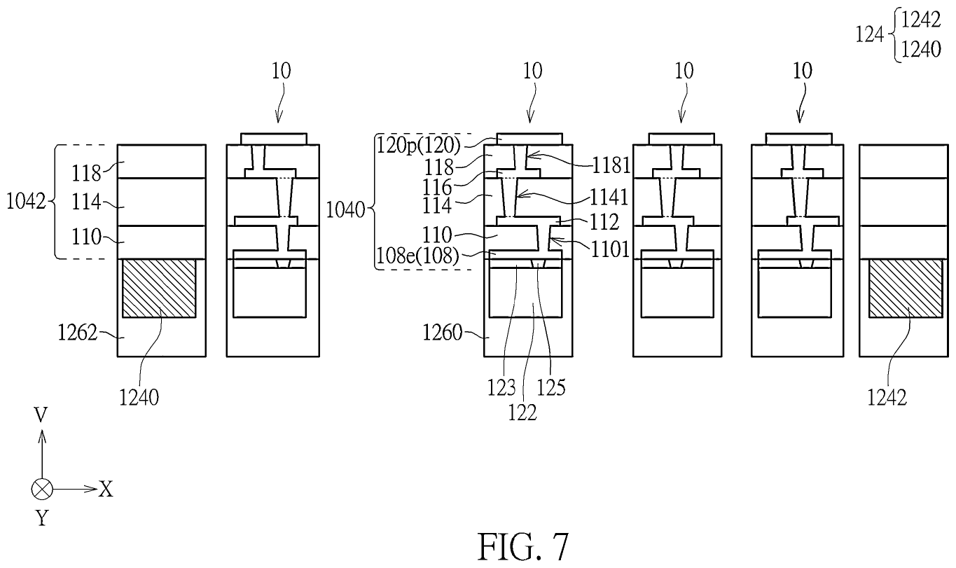

Subsequently, the release layer 128 and the carrier 130 are removed. Then, as shown in FIG. 7, the electronic components 122 and the structural unit 124 can be separated from each other by a cutting process. The cutting process is performed along Direction V, and a plurality of electronic devices 10 are obtained after the cutting process. For example, each of the electronic device 10 may include at least one electronic component 122, an encapsulation layer portion 1260 corresponding to the electronic component 122, and a circuit structure portion 1040 corresponding to the electronic component 122. The encapsulation layer portion 1260 is a portion of the encapsulation layer 126 shown in FIG. 6, and the circuit structure portion 1040 is a portion of the circuit structure 104 shown in FIG. 6, but not limited thereto.

Furthermore, the structural 124 (e.g., the portion 1240 and the portion 1242), an encapsulation layer portion 1262 corresponding to the structural unit 124 and a circuit structure portion 1042 corresponding to the structural unit 124 can be removed. The encapsulation layer portion 1262 is a portion of the encapsulation layer 126 shown in FIG. 6, and the circuit structure portion 1042 is a portion of the circuit structure 104 shown in FIG. 6, but not limited thereto.

In an exemplary drawing of an embodiment analogous to the present disclosure, although each of the electronic components 122 of the electronic devices 10 obtained by the cutting process is electrically connected to the circuit structure portion 1040 through only one connecting conductive member 125, the electronic component 122 of the electronic device 10 may actually be electrically connected to the circuit structure portion 1040 through more than one connecting conductive member 125.

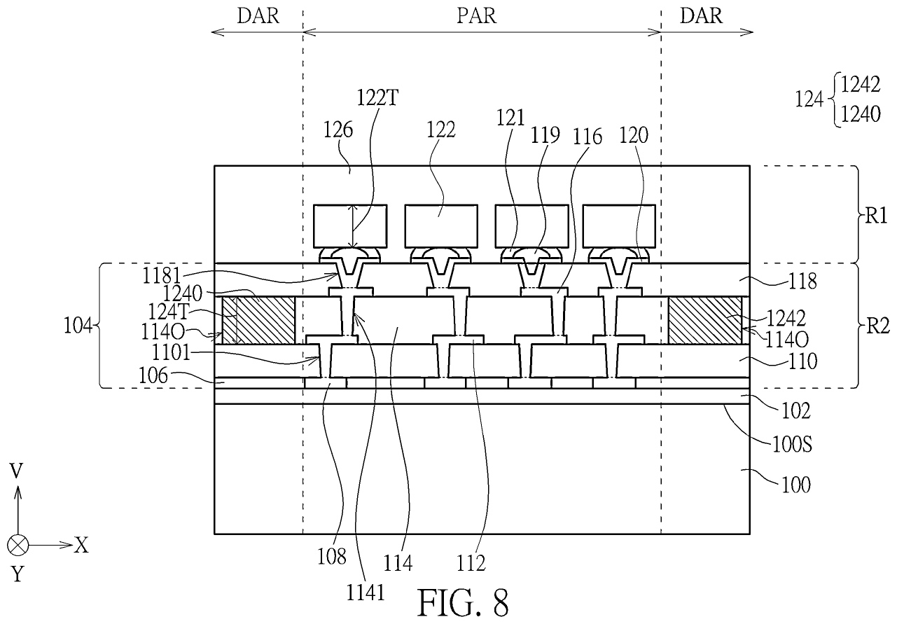

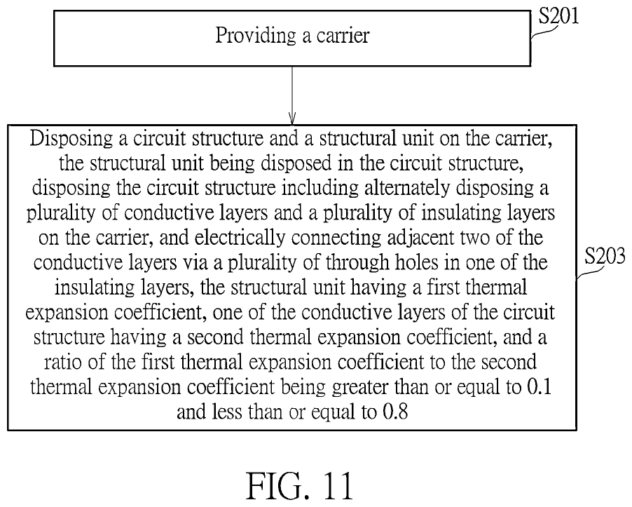

Please refer to FIG. 8 to FIG. 11, wherein FIG. 8 to FIG. 10 are schematic diagrams illustrating a manufacturing method of an electronic device according to a third embodiment of the present disclosure, and FIG. 11 is a flowchart schematically illustrating the manufacturing method of the electronic device in the third embodiment. It is to be noted that the steps illustrated in FIG. 11 may not be exhaustive, and additional steps may be performed before, after, or between any of the existing steps. In addition, some of the steps may be performed simultaneously or in a different order other than that shown in FIG. 11. The third embodiment differs from the first embodiment in that the structural unit 124 in this embodiment may be disposed in the second region R2, or the structural unit 124 may be disposed in the circuit structure 104.

First of all, as shown in FIG. 8, a carrier 100 is provided in Step S201. Subsequently, a release layer 102 may be formed on the carrier 100. Subsequently, in Step 203, a circuit structure 104 and a structural unit 124 are disposed on the carrier 100, and the structural unit 124 is disposed in the circuit structure 104. As shown in FIG. 8, a plurality of conductive layers and a plurality of insulating layers may be alternately disposed on the carrier 100, and adjacent two of the conductive layers may be electrically connected via a plurality of through holes in one of the insulating layers. For example, an insulating layer 106, a conductive layer 108, an insulating layer 110, through holes 1101 in the insulating layer 110, a conductive layer 112, an insulating layer 114, through holes 1141 in the insulating layer 114, a conductive layer 116, an insulating layer 118, through holes 1181 in the insulating layer 118, and a conductive layer 120 are sequentially formed on the carrier 100, but not limited thereto. The number of the conductive layers and the number of the insulating layers may be adjusted according to demands, and the order of the above process is only an example, which may be modified according to demands.

Furthermore, when any one of the insulating layers (e.g., the insulating layer 114) in the circuit structure 104 is being formed, at least one opening (e.g., openings 1140) is formed in the insulating layer (e.g., the insulating layer 114), and the at least one opening (e.g., the opening 1140) is disposed in the non-package area DAR. Subsequently, the structural unit 124 is formed in the at least one opening (e.g., the opening 1140). The structural unit 124 can be disposed in the insulating layer 114 and disposed in the non-package area DAR. In the cross-sectional diagram, the structural unit 124 has a maximum thickness 124T, which may be equal or unequal to the thickness (not shown) of the opening 1140 of the insulting layer, where the structural unit 124 disposed. It is to be noted that the shape the at least one opening (e.g., the opening 1140) formed in the any one of the insulating layers (e.g., the insulating layer 114) may include, for example, a rectangle, but not limited thereto. The shape may include other shapes, such as trapezoid, according to requirements, or it may include arc edges or an irregular shape.

There are a variety of ways to dispose the structural unit 124 in the second region R2. The structural unit 124 may be disposed in at least one insulating layer of the circuit structure 104. For example, the structural unit 124 may be disposed in an opening of at least one of the insulating layer 110, the insulating layer 114 and the insulating layer 118, or the structural unit 124 may be disposed in openings of any two of the insulating layer 110, the insulating layer 114 and the insulating layer 118.

As shown in FIG. 8, the structural unit 124 has a first thermal expansion coefficient, one of the conductive layers of the circuit structure 104 has a second thermal expansion coefficient. When the structural unit 124 is disposed in the second region R2, or when the structural unit 124 is disposed in the circuit structure 104, or when the structural unit 124 and the electronic components 122 are not overlapped in the direction (e.g., Direction X or Direction Y) parallel to the surface 100S of the carrier 100, a ratio of the first thermal expansion coefficient of the material of the structural unit 124 to the second thermal expansion coefficient of the material of the one of the conductive layers of the circuit structure 104 (i.e., the first thermal expansion coefficient/the second thermal expansion coefficient) is greater than or equal to 0.1 and less than or equal to 0.8, but not limited thereto. The ratio may be greater than or equal to 0.15 and less than or equal to 0.75, or greater than or equal to 0.2 and less than or equal to 0.7. When the material of the structural unit 124 and the material of one of the conductive layers of the circuit structure 104 meet the range of the ratio of thermal expansion coefficients, the warpage of the overall structure can be effectively suppressed so as to improve yield and reliability of the electronic device.

In some embodiments, the structural unit 124 may include glass, silicon nitride, silicon oxide, any other suitable ceramic material with a low thermal expansion coefficient, or a combination of the foregoing, but not limited thereto. In some embodiments, the first thermal expansion coefficient of the structural unit 124 may be greater than or equal to 1.7 ppm/° C. and less than or equal to 13.6 ppm/° C., or may be greater than or equal to 1.7 ppm/° C. and less than or equal to 11 ppm/° C., or may be greater than or equal to 1.7 ppm/° C. and less than or equal to 9 ppm/° C., or may be greater than or equal to 1.7 ppm/° C. and less than or equal to 7 ppm/° C., but not limited to this. With such a designed ratio of the first thermal expansion coefficient of the structural unit 124 to the second thermal expansion coefficient of the one of the conductive layers of the circuit structure 104, a warping direction of the structure in the non-package area DAR may be, for example, opposite to a warping direction of the structure in the package area PAR so as to suppress the warpage of the overall structure.

Subsequently, electronic components 122 may be disposed after the circuit structure 104 and the structural unit 124 are disposed. For example, the electronic components 122 may be disposed on the insulating layer 118 and the conductive layer 120, and the electronic components 122 may be electrically connected to the conductive layer 120 through the connecting conductive members 119, but not limited thereto. Furthermore, the electronic components 122 and the structural unit 124 are not overlapped in both the direction (Direction V) perpendicular to the surface 100S of the carrier 100 and the direction (Direction X or Direction Y) parallel to the surface 100S of the carrier 100. In this embodiment and in the cross-sectional diagram (scale for reference only), the structural unit 124 has a maximum thickness 124T, and the maximum thickness 124T is greater than or equal to the maximum thickness 122T of the electronic component 122. In some embodiments and in the cross-sectional diagram (scale for reference only), the maximum thickness 124T 1 of the structural unit 124 may not be equal to the maximum thickness 122T of the electronic component 122.

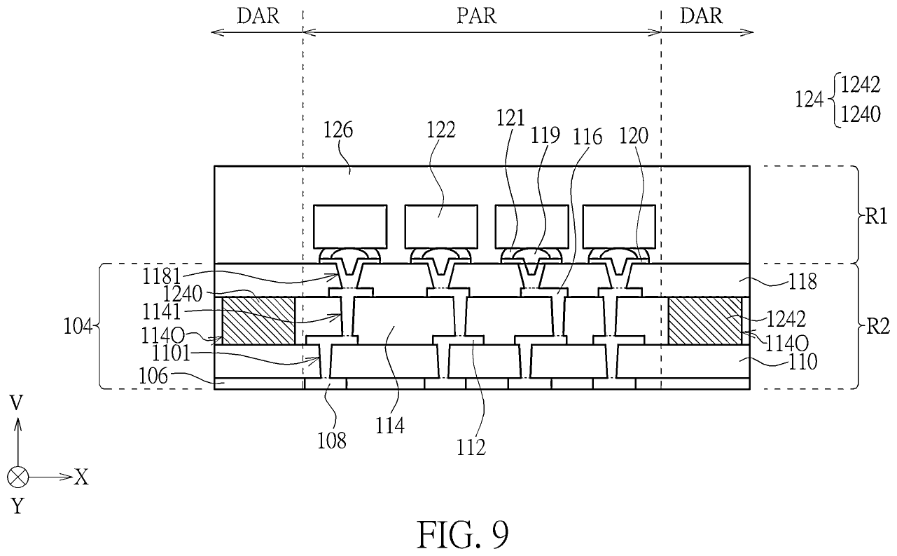

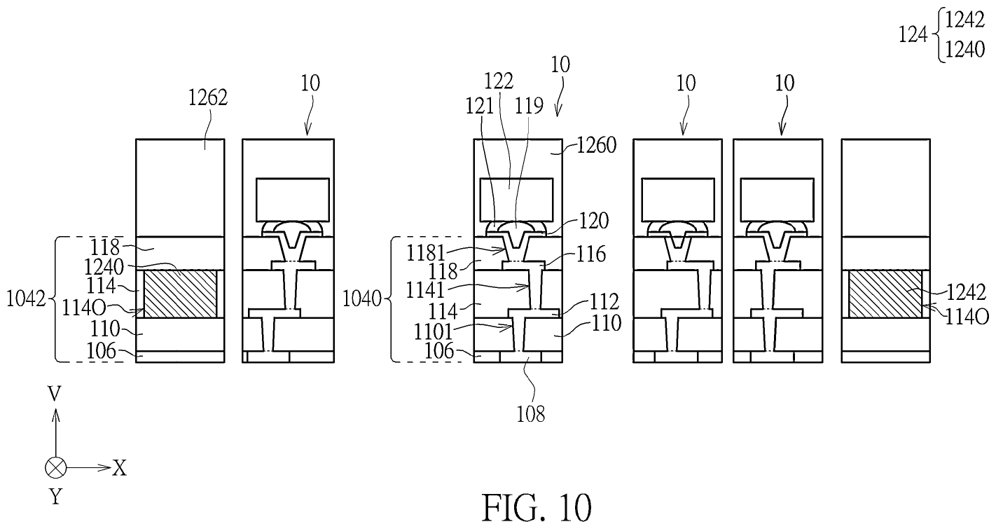

Subsequently, an encapsulation layer 126 is formed on the electronic components 122. In this embodiment, the first thermal expansion coefficient of the structural unit 124 may be less than the thermal expansion coefficient of the encapsulation layer 126, but not limited thereto. Subsequently, as shown in FIG. 9, the release layer 102 and the carrier 100 are removed. Then, as shown in FIG. 10, the electronic components 122 and the structural unit 124 can be separated from each other by the cutting process. The cutting process is performed along Direction V, a plurality of electronic devices 10 are obtained after the cutting process, and the structural unit 124 (e.g., the portion 1240 and the portion 1242) can be removed. In an exemplary drawing of an embodiment analogous to the present disclosure, although each of the electronic components 122 of the electronic devices 10 obtained by the cutting process is electrically connected to the circuit structure portion 1040 through only one connecting conductive member 119, the electronic component 122 of the electronic device 10 may actually be electrically connected to the circuit structure portion 1040 through more than one connecting conductive member 119.

Therefore, in some embodiments, a manufacturing method of the electronic device 10 includes, but not limited to, the following steps:
S201: providing a carrier; and
S203: disposing a circuit structure and a structural unit on the carrier, wherein the structural unit is disposed in the circuit structure, and wherein the step of disposing the circuit structure includes alternately disposing a plurality of conductive layers and a plurality of insulating layers on the carrier and electrically connecting adjacent two of the conductive layers via a plurality of through holes in one of the insulating layers; the structural unit has a first thermal expansion coefficient; one of the conductive layers of the circuit structure has a second thermal expansion coefficient; and a ratio of the first thermal expansion coefficient to the second thermal expansion coefficient is greater than or equal to 0.1 and less than or equal to 0.8.

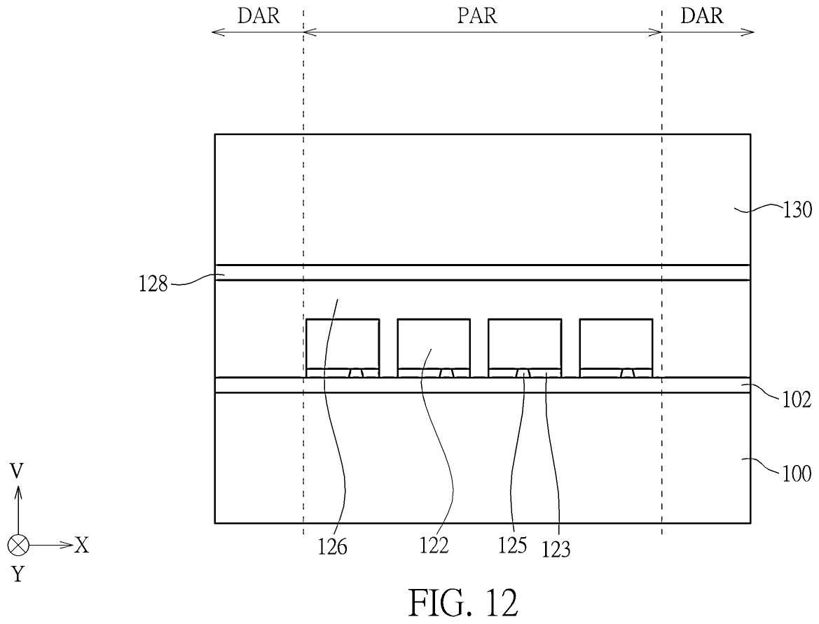

Please refer to FIG. 12 to FIG. 14. FIG. 12 to FIG. 14 are schematic diagrams illustrating a manufacturing method of an electronic device according to a fourth embodiment of the present disclosure. The fourth embodiment differs from the third embodiment in that the electronic components 122 are disposed before the circuit structure 104 is disposed, and differs from the second embodiment in that the structural unit 124 may be disposed in the second region R2, or the structural unit 124 may be disposed in the circuit structure 104. First of all, as shown in FIG. 12, a carrier 100 is provided. Subsequently, a release layer 102 is formed on the carrier 100. Next, the electronic components 122 are disposed on the release layer 102. A plurality of insulating structures 123 respectively are disposed between the electronic components 122 and the release layer 102, or between the electronic components 122 and the carrier 100. The material of the insulating structures 123 may refer to the description with reference to FIG. 5. Subsequently, an encapsulation layer 126 is formed on the electronic components 122 and the structural unit 124. Next, a release layer 128 and a carrier 130 are sequentially formed on the encapsulation layer 126.

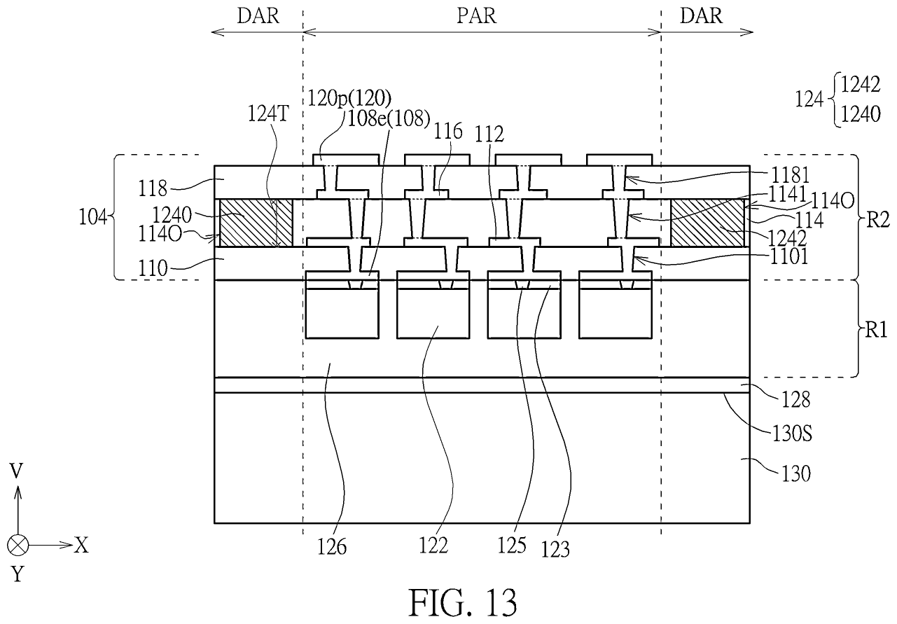

Subsequently, the structure in FIG. 12 is 180-degree flipped, and the release layer 102 and the carrier 100 are then removed. Then, as shown in FIG. 13, the circuit structure 104 and the structural unit 124 are formed on the carrier 130. In detail, the circuit structure 104 and the structural unit 124 may be formed on the electronic components 122 and the encapsulation layer 126. For example, a conductive layer 108, an insulating layer 110, through holes 1101 in the insulating layer 110, a conductive layer 112, an insulating layer 114, through holes 1141 in the insulating layer 114, a conductive layer 116, an insulating layer 118, through holes 1181 in the insulating layer 118, and a conductive layer 120 are sequentially formed on the insulating structures 123 and the encapsulation layer 126, but not limited thereto. The number of the conductive layers and the number of the insulating layers may be adjusted according to demands, and the order of the above process is only an example, which may be modified according to demands.

Furthermore, when any one of the insulating layers (e.g., the insulating layer 114) in the circuit structure 104 is being formed, at least one opening (e.g., the opening 1140) is formed in the insulating layer (e.g., the insulating layer 114), and the at least one opening (e.g., the opening 1140) is disposed in the non-package area DAR. Subsequently, the structural unit 124 is formed in the at least one opening (e.g., the opening 1140). Therefore, the structural unit 124 is disposed in the insulating layer 114 and disposed in the non-package area DAR. In the cross-sectional diagram, the structural unit 124 has a maximum thickness 124T, which may be equal or unequal to the thickness (not shown) of the opening (e.g., the opening 1140) of the insulting layer, where the structural unit 124 disposed.

There are a variety of ways to dispose the structural unit 124 in the second region R2. The structural unit 124 may be disposed in at least one insulating layer of the circuit structure 104. For example, the structural unit 124 may be disposed in an opening of at least one of the insulating layer 110, the insulating layer 114 and the insulating layer 118, or the structural unit 124 may be disposed in openings of any two of the insulating layer 110, the insulating layer 114 and the insulating layer 118.

As shown in FIG. 13, the electronic components 122 and the structural unit 124 are not overlapped in both Direction V perpendicular to the surface 130S of the carrier 130 and Direction X (or Direction Y) parallel to the surface 130S of the carrier 130, but not limited thereto. When the structural unit 124 is disposed in the second region R2, or when the structural unit 124 is disposed in the circuit structure 104, or when the structural unit 124 and the electronic components 122 are not overlapped in the direction (e.g., Direction X or Direction Y) parallel to the surface 130S of the carrier 130, a ratio of the first thermal expansion coefficient of the material of the structural unit 124 to the second thermal expansion coefficient of the material of the one of the conductive layers of the circuit structure 104 (i.e., the first thermal expansion coefficient/the second thermal expansion coefficient) is greater than or equal to 0.1 and less than or equal to 0.8, but not limited thereto. In some embodiments, the ratio may be greater than or equal to 0.15 and less than or equal to 0.75, or greater than or equal to 0.2 and less than or equal to 0.7. When the material of the structural unit 124 and the material of one of the conductive layers of the circuit structure 104 meet the range of the ratio of thermal expansion coefficients, the warpage of the overall structure can be effectively suppressed so as to improve yield and reliability of the electronic device.

In some embodiments, the structural unit 124 may include glass, silicon nitride, silicon oxide, any other suitable ceramic material with a low thermal expansion coefficient, or a combination of the foregoing, but not limited thereto. In some embodiments, the first thermal expansion coefficient of the structural unit 124 may be greater than or equal to 1.7 ppm/° C. and less than or equal to 13.6 ppm/° C., or may be greater than or equal to 1.7 ppm/° C. and less than or equal to 11 ppm/° C., or may be greater than or equal to 1.7 ppm/° C. and less than or equal to 9 ppm/° C., or may be greater than or equal to 1.7 ppm/° C. and less than or equal to 7 ppm/° C., but not limited to this. With such a designed ratio of the first thermal expansion coefficient of the structural unit 124 to the second thermal expansion coefficient of the one of the conductive layers of the circuit structure 104, a warping direction of the structure in the non-package area DAR may be, for example, opposite to a warping direction of the structure in the package area PAR so as to suppress warping of the overall structure.

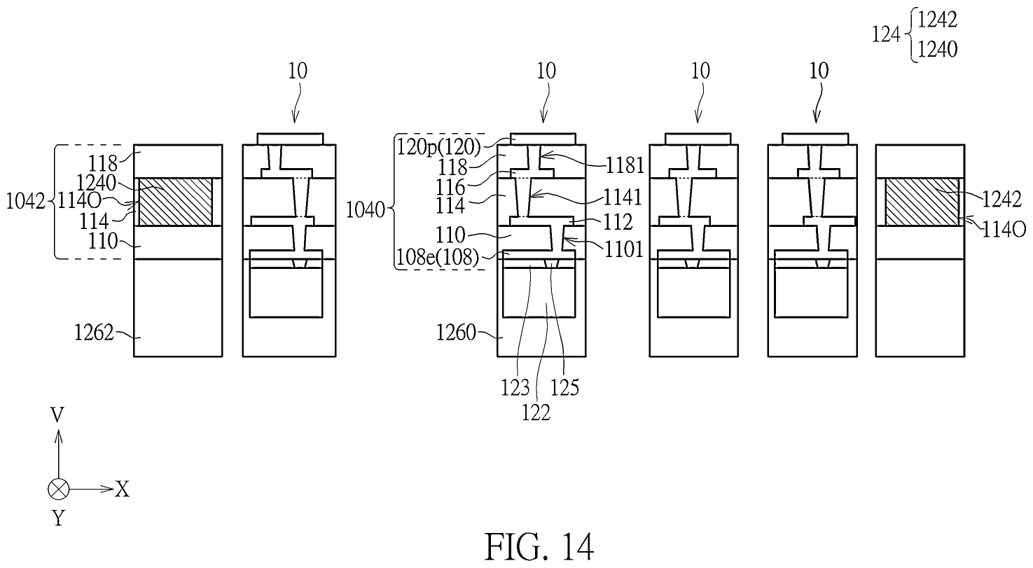

Subsequently, the release layer 128 and the carrier 130 are removed. Next, as shown in FIG. 14, the electronic components 122 and the structural unit 124 can be separated from each other by the cutting process. The cutting process is performed along Direction V, a plurality of electronic devices 10 are obtained after the cutting process, and the structural unit 124 (e.g., the portion 1240 and the portion 1242) is removed. In an exemplary drawing of an embodiment analogous to the present disclosure, although each of the electronic components 122 of the electronic devices 10 obtained by the cutting process is electrically connected to the circuit structure portion 1040 through only one connecting conductive member 125, the electronic component 122 of the electronic device 10 may actually be electrically connected to the circuit structure portion 1040 through more than one connecting conductive member 125.

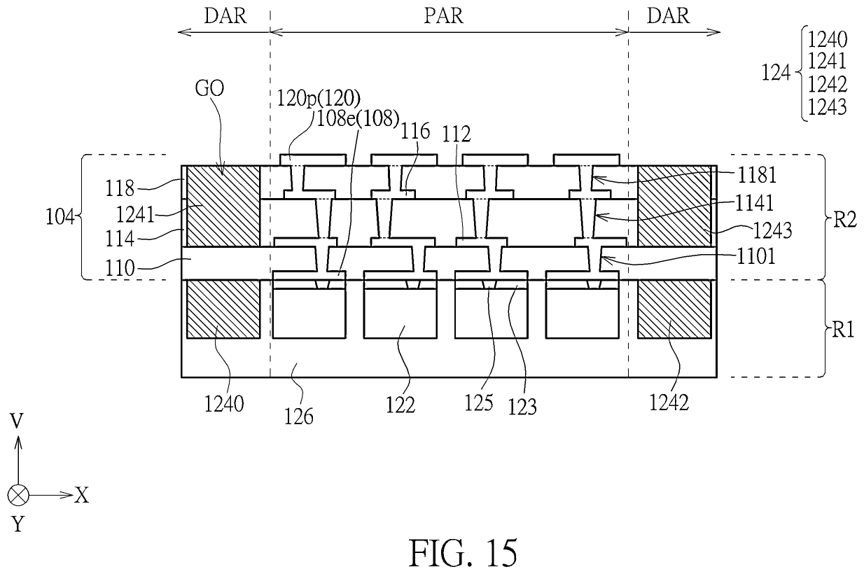

Please refer to FIG. 15. FIG. 15 is a schematic diagram illustrating a structure formed before a cutting process of a manufacturing method of an electronic device according to a fifth embodiment of the present disclosure. The structure in FIG. 15 may be, for example, a structure formed after the removal of the release layer 128 and the carrier 130 and before the cutting process. In this embodiment, the structural unit 124 may include a portion 1240, a portion 1241, a portion 1242 and/or a portion 1243. The portion 1240 and the portion 1242 may be disposed, for example, in the first region R1 in the non-package area DAR, and the portion 1240 and the portion 1242 may be disposed, for example, in the second region R2 in the non-package area DAR, but not limited thereto.

The portion 1241 and the portion 1243 may be disposed, for example, in the openings of the insulating layers of the circuit structure 104, e.g., the openings (not shown) formed in the insulating layer 114 and the openings (not shown) formed in the insulating layer 118. The openings (not shown) formed in the insulating layer 114 and the openings (not shown) formed in the insulating layer 118, for example, may be combined into large openings GO. The portion 1241 and the portion 1243, for example, may be disposed in different openings GO, but not limited thereto. In other words, the portion 1241 and the portion 1243 may be disposed in multiple insulating layers (e.g., the insulating layer 114 and the insulating layer 118), but not limited thereto.

In some embodiments, the thermal expansion coefficient of the material of the portion 1240 and/or portion 1242 of the structural unit 124 is different from the thermal expansion coefficient of the material of the portion 1241 and/or portion 1243 of the structural unit 124.

In some embodiments, a ratio of the thermal expansion coefficient of the material of the portion 1240 and/or the portion 1242 of the structural unit 124 to the thermal expansion coefficient of the material of one of the conductive layers of the circuit structure 104 is greater than or equal to 1.2 and less than or equal to 2, but not limited thereto. The ratio may also be greater than or equal to 1.3 and less than or equal to 1.9, or greater than or equal to 1.4 and less than or equal to 1.8. In some embodiments, a ratio of the thermal expansion coefficient of the material of the portion 1241 and/or portion 1243 of the structural unit 124 to the thermal expansion coefficient of the material of one of the conductive layers of the circuit structure 104 is greater than or equal to 0.1 and less than or equal to 0.8, but not limited thereto. In some embodiments, the ratio may be greater than or equal to 0.15 and less than or equal to 0.75, or greater than or equal to 0.2 and less than or equal to 0.7. Through the design of the above-mentioned portions of the structural unit 124, the warping direction of the structure in the non-package area DAR and the warping direction of the structure in the package area PAR can be opposite, thereby suppressing the warpage of the whole structure.

In some embodiments, in Direction V, the portion 1240 of the structural unit 124 may be or may not be overlapped with the portion 1241 of the structural unit 124. In some embodiments, in Direction V, the portion 1242 of the structural unit 124 may be or may not be overlapped with the portion 1243 of the structural unit 124. In some embodiments, in Direction X (or Direction Y), the width (not shown) of the portion 1240 and the width (not shown) of the portion 1241 may be the same or different. In some embodiments, in Direction X (or Direction Y), the width (not shown) of the portion 1242 and the width (not shown) of the portion 1243 may be the same or different. In some embodiments, in the cross-sectional diagram, the maximum thickness (not shown) of the portion 1240 and the maximum thickness (not shown) of the portion 1241 may be the same or different. In some embodiments, in the cross-sectional diagram, the maximum thickness (not shown) of the portion 1242 and the maximum thickness (not shown) of the portion 1243 may be the same or different. In some embodiments, in the cross-sectional diagram, the maximum thickness (not shown) of the portion 1240 or the portion 1242 may be greater than or equal to the maximum thickness (not shown) of the electronic component 122. In some embodiments, in the cross-sectional diagram, the minimum distance between the portion 1240 (or the portion 1242) and the electronic component 122 in Direction X may be different from (e.g., greater than or less than) the minimum distance between adjacent electronic components 122.

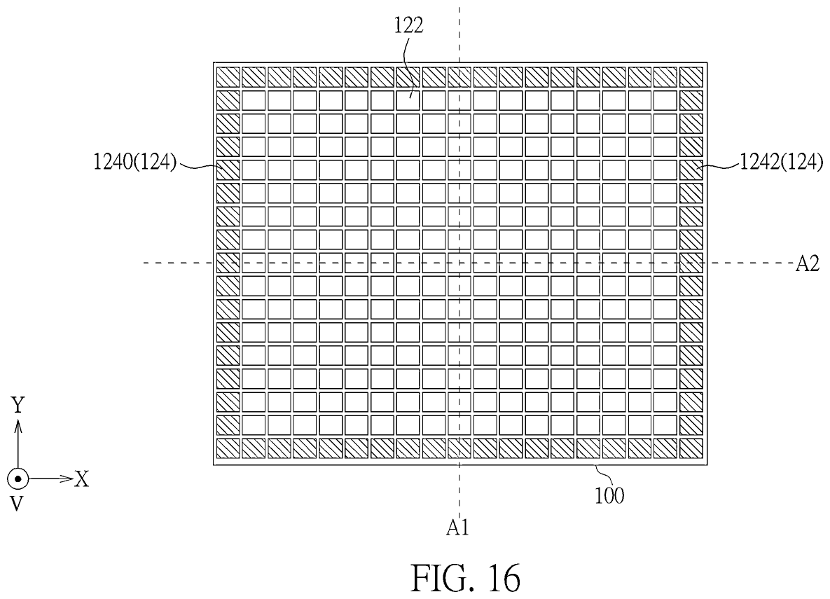

Please refer to FIG. 16. FIG. 16 is a top view schematically illustrating a structural unit and electronic components disposed on a carrier according to a sixth embodiment of the present disclosure. In some embodiments, in the top view direction (e.g., Direction V) or in a top view (e.g., FIG. 16) of the electronic components 122 and the structural unit 124, portions (e.g., shown by shaded portions) of the structural unit 124 can surround the electronic components 122. In comparison with the configuration, where no structural unit 124 is provided and the electronic components 122 are distributed all over the carrier 100, the warping level at corners of the configuration of the present disclosure is significantly reduced. In some embodiments, the electronic components 122 may be disposed in sequence, for example, along Direction X and Direction Y. For example, the plurality of electronic components 122 may be arranged as an array, but not limited thereto. In some embodiments, the portions of the structural unit 124 may be disposed in sequence, for example, along Direction X and Direction Y. In a top view, the portions of the structural unit 124, for example, may surround the electronic components 122. The configuration of the electronic components 122 and the portions of the structural unit 124 shown in FIG. 16 is for exemplification only, and may be modified according to the shape and the dimension of the carrier 100. It is understood that the top-view diagram shown in FIG. 16 may be applied to any of the embodiments illustrated with reference to FIG. 1 to FIG. 15.

In some embodiments, the portions (e.g., shown by shaded portions) of the structural unit 124 can be connected to form a structural unit having, for example, an annular shape, but not limited thereto. For example, a virtual line A1 (e.g., a virtual line extending along Direction Y) penetrates through several electronic components 122 and two portions of the structural unit 124, but not limited thereto. The number of portions of the structural unit 124, through which the virtual line A1 penetrates, may vary with designs. For another example, a virtual line A2 (e.g., a virtual line extending along Direction X) penetrates through several electronic components 122 and two portions of the structural unit 124, but not limited thereto. The number of portions of the structural unit 124, through which the virtual line A2 penetrates, may vary with designs. In some embodiments, multiple portions of the structural unit 124 may be connected to each other.

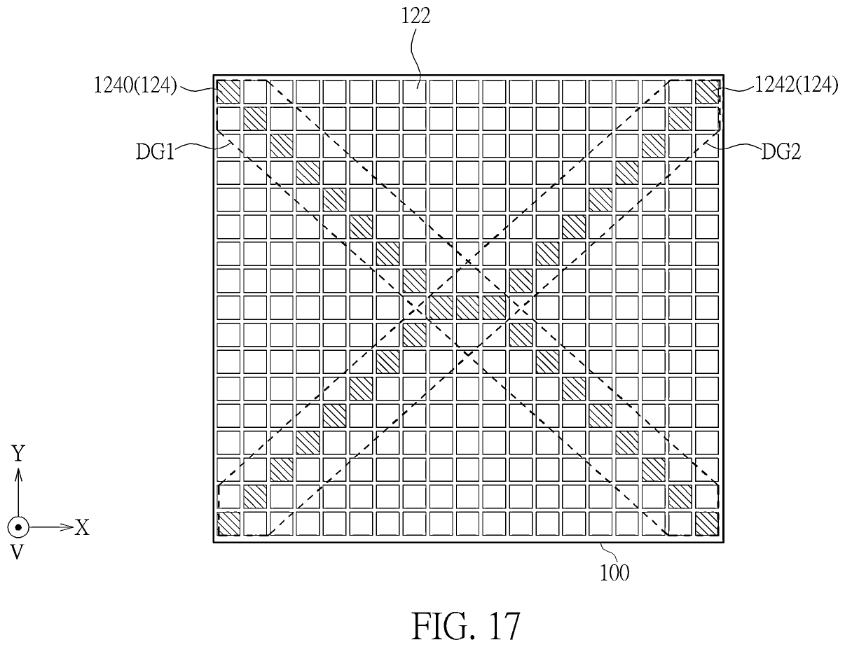

Please refer to FIG. 17. FIG. 17 is a top view schematically illustrating a structural unit and electronic components disposed on a carrier according to a seventh embodiment of the present disclosure. In some embodiments, a carrier 100 includes two diagonal zones (e.g., a diagonal zone DG1 and a diagonal zone DG2), and at least a portion of the structural unit 124 is disposed in the two diagonal zones. For example, a portion of the structural unit 124 may be disposed in the diagonal zone DG1, and another portion of the structural unit 124 may be disposed in the diagonal zone DG2. In some embodiments, the shape of the structural unit 124 may be approximate an X shape, but not limited thereto. In comparison with the configuration, where no structural unit 124 is provided and the electronic components 122 are distributed all over the carrier 100, the warping level at corners of the configuration of the present disclosure is significantly reduced. It is understood that the top-view diagram shown in FIG. 17 may be applied to any of the embodiments illustrated with reference to FIG. 1 to FIG. 15.

In some embodiments, the carrier 100 may have a non-rectangular shape (e.g., circle, oval, polygon, or a free shape). In this case, a minimum virtual rectangle capable of framing the carrier may be defined, and the diagonal zone DG1 and the diagonal zone DG2 may be defined with diagonals of the virtual rectangle.

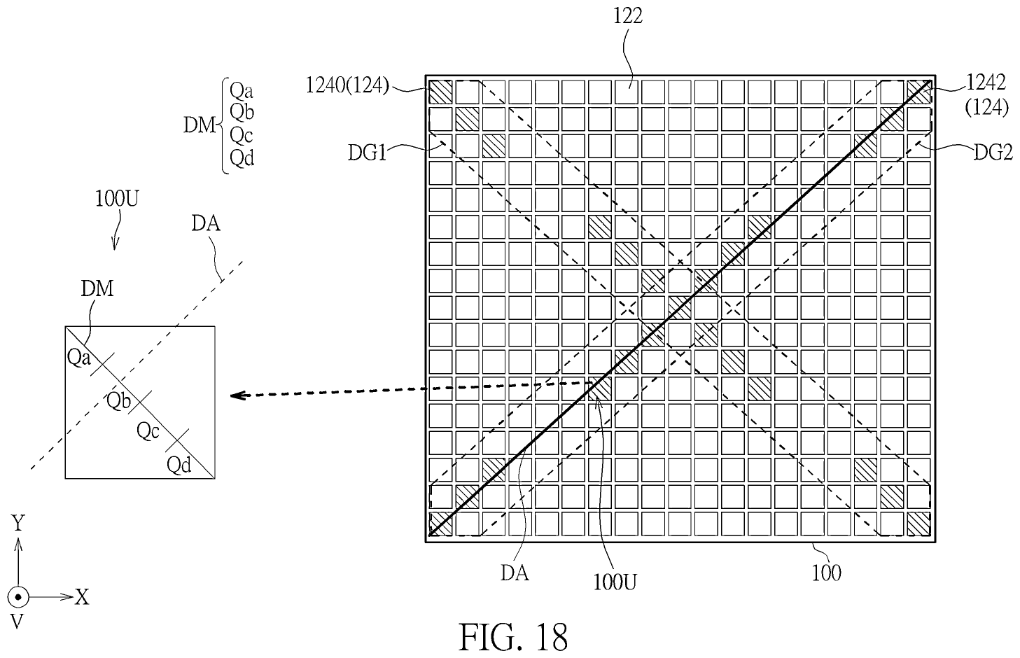

Please refer to FIG. 18. FIG. 18 is a top view schematically illustrating a structural unit and electronic components disposed on a carrier according to an eighth embodiment of the present disclosure. The eighth embodiment differs from the seventh embodiment in that a smaller portion of the structural unit 124 is disposed in the diagonal zone DG1 and the diagonal zone DG2 in this embodiment, so that a total amount of the electronic components 122 may be increased and a higher yield can be obtained.

As shown in FIG. 18, the layout of the electronic components 122 and the portions (e.g., shown by shaded portions) of the structural unit 124 may be designed as follows. A diagonal line DA may be defined on the carrier 100. The diagonal line DA may extend from the upper right corner of the carrier 100 to the lower left corner of the carrier 100. In other words, the diagonal line DA may be a line linking two opposite corners of the carrier 100. Furthermore, the carrier 100 is divided into a plurality of sub-units 100U. Take one of the sub-units 100U as an example. The sub-unit 100U may be equally divided into four parts (e.g., part Qa, part Qb, part Qc and part Qd in order) along a direction perpendicular to the diagonal line DA.

When the diagonal line DA penetrates through the part Qb or the part Qc in the middle, the warping level can be effectively reduced by disposing the portion of the structural unit 124 in this sub-unit 100U, but not limited thereto. Contrary to the diagonal line DA penetrating through the part Qb or the part Qc in the middle, when the diagonal line DA penetrates through the part Qa or the part Qd, the reduction of the warping level is less significant as the portion of the structural unit 124 is disposed in this sub-unit 100U. In consideration of manufacturing capacity, it is preferred to dispose, for example, the electronic component 122 in this sub-unit 100U, but not limited thereto. By designing the layout of the portions of the structural unit 124 and the electronic components 122 in this manner, not only can the warpage of the overall structure be reduced, but also the amount of the electronic components 122 can be increased. For example, compared with the configuration having no portions of the structural unit 124 but having electronic components 122 disposed all over the carrier 100, the number of the electronic components 122 in this embodiment is decreased by only about 7.7%, but the warpage of corners and edges can still be reduced, thereby reducing the overall warpage. It is to be noted that the top view shown in FIG. 18 may be applied to any of the embodiments illustrated with reference to FIG. 1 to FIG. 15.

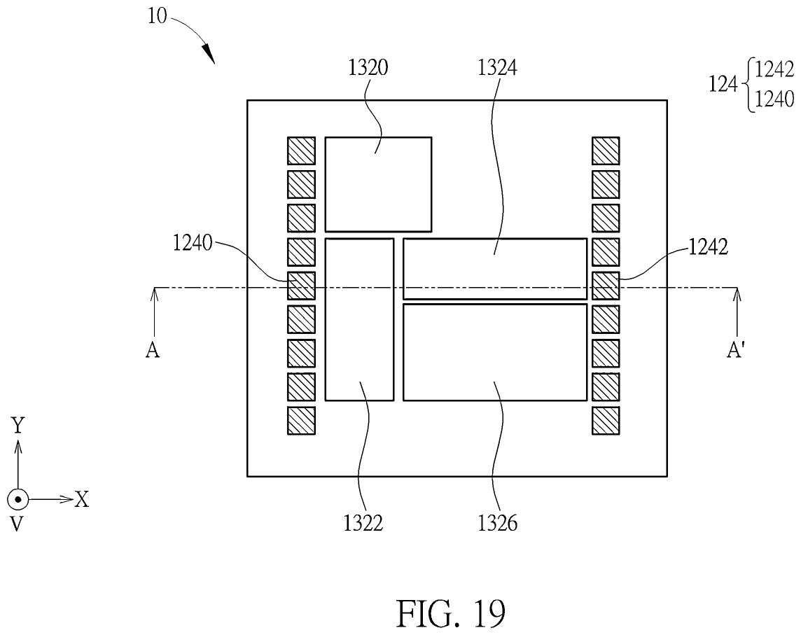

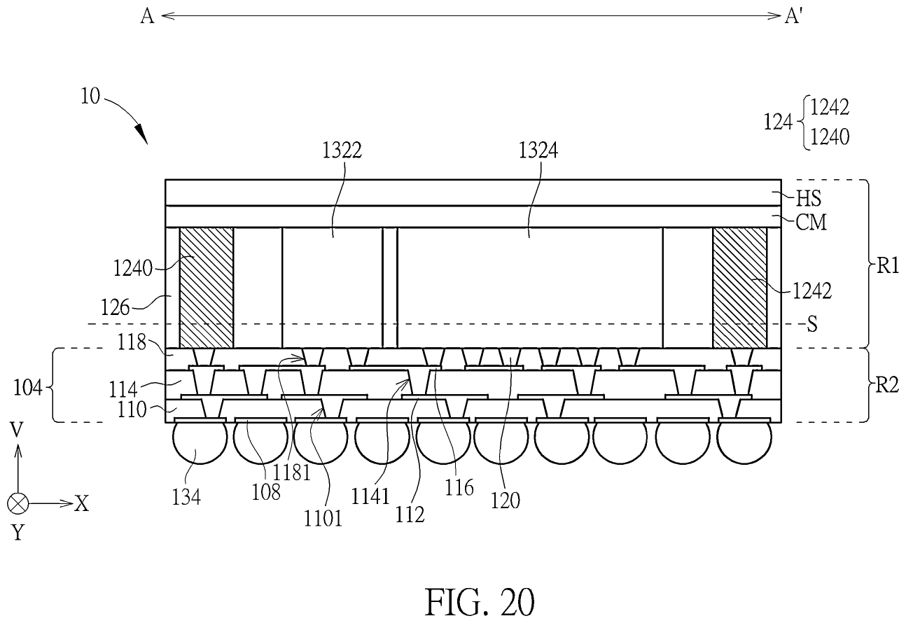

Please refer to FIGS. 19 and 20. FIG. 19 is a top view schematically illustrating a structural unit and electronic components of an electronic device according to a ninth embodiment of the present disclosure. FIG. 20 is a cross-sectional view schematically illustrating the electronic device in the ninth embodiment. As shown in FIG. 19, the electronic device 10 may include a plurality of electronic components, e.g., an electronic component 1320, an electronic component 1322, an electronic component 1324 and/or an electronic component 1326, but not limited thereto. The number of the electronic components may vary with demands. For example, the electronic component 1320 may be a Micro Electro Mechanical System (MEMS) device, the electronic component 1322 may be a Radio Frequency (RF) device, the electronic component 1324 may be a memory device, and the electronic component 1326 may be a logic device, but not limited thereto. The types of the above electronic components may vary with demands, and positions or relative dimensions of the above electronic components may also vary with demands.

The structural unit 124 is disposed near several electronic components. For example, it is disposed near the electronic component 1320, the electronic component 1322, the electronic component 1324 and the electronic component 1326. Viewing from a top view direction of the electronic device (e.g., Direction V), or in a top view, at least a portion of the structural unit 124 is disposed between adjacent two of the electronic components. As shown in FIG. 19, different portions of the structural unit 124, e.g., the shaded portions at the left side of the electronic components or the shaded portions at the right side of the electronic components, may be disposed at opposite sides of at least two adjacent electronic components in Direction X. In addition, different portions of the structural unit 124, e.g., the shaded portions at the left side of the electronic components or the shaded portions at the right side of the electronic components, may include divided portions distributed along Direction Y, but not limited thereto.

The cross-sectional structure shown in FIG. 20 may correspond to the line A-A′ shown in FIG. 19. The electronic device 10 may include a circuit structure 104, and a plurality of electronic components (e.g., the electronic component 1320, the electronic component 1322, the electronic component 1324 and the electronic component 1326) electrically connected to the circuit structure 104. As illustrated in FIG. 20, the electronic components, e.g., the electronic component 1320, the electronic component 1322, the electronic component 1324 and the electronic component 1326, are overlapped with the circuit structure 104. The circuit structure 104 includes a plurality of conductive layers and at least one insulating layer, and the conductive layers are electrically connected to each other through the through holes in the at least one insulating layer. For example, the circuit structure 104 may include a conductive layer 108, an insulating layer 110, through holes 1101 in the insulating layer 110, a conductive layer 112, an insulating layer 114, through holes 1141 in the insulating layer 114, a conductive layer 116, an insulating layer 118, through holes 1181 in the insulating layer 118, and a conductive layer 120, but not limited thereto. The manufacturing method of the circuit structure 104 may refer to the above-described embodiments.

Furthermore, the conductive layer 108 may include a plurality of contact pads, and the electronic device 10 may include a plurality of soldering elements 134 (e.g., solder balls) disposed at a side of the contact pads of the conductive layer 108 and electrically connected to the conductive layer 108. The electronic components are at least partially overlapped with the structural unit 124 in a cross-sectional plane S of the electronic device. The cross-sectional plane S is substantially parallel to, for example, a surface of any of the insulating layers of the circuit structure 104 or a surface of any of the conductive layers. The cross-sectional plane S is substantially parallel to a plane that is parallel to both Direction X and Direction Y.

The structural unit 124 has a first thermal expansion coefficient, one of the conductive layers of the circuit structure 104 has a second thermal expansion coefficient, and a ratio of the first thermal expansion coefficient to the second thermal expansion coefficient is greater than or equal to 1.2 and less than or equal to 2.

In some embodiments, the electronic component 1320, the electronic component 1322, the electronic component 1324 and the electronic component 1326 may be electrically connected with the circuit structure 104 via at least an interposer (not shown), and the interposer (not shown) may be disposed between the circuit structure 104 and the electronic components (e.g., the electronic component 1320, the electronic component 1322, the electronic component 1324 and the electronic component 1326), but not limited thereto.

In this embodiment, the structural unit 124 may be disposed in the first region R1, and the structural unit 124 may be selectively electrically connected to the conductive layers in the circuit structure 104, but not limited thereto. In this embodiment, the encapsulation layer 126 may be disposed near the structural unit 124 and the electronic components (e.g., the electronic component 1320, the electronic component 1322, the electronic component 1324 and the electronic component 1326). The encapsulation layer 126 may surround at least the side surfaces of the structural unit 124 and the electronic components (e.g., the electronic component 1320, the electronic component 1322, the electronic component 1324 and the electronic component 1326). A surface of the encapsulation layer 126, which is away from the circuit structure 104, is substantially aligned with the surfaces of the electronic components (e.g., the electronic component 1320, the electronic component 1322, the electronic component 1324 and the electronic component 1326) or the surface of the structural unit 124, but not limited thereto.

In this embodiment, a heat-dissipating element HS may be disposed on the encapsulation layer 126, the structural unit 124 and the electronic components (e.g., the electronic component 1320, the electronic component 1322, the electronic component 1324 and the electronic component 1326). An adhesive material CM may be selectively disposed between the heat-dissipating element HS and the encapsulation layer 126, the structural unit 124 and the electronic components. The adhesive material CM can be used to attach the heat-dissipating element HS onto the structural unit 124 and the electronic components.

In some embodiments, the adhesive material CM (e.g., a conductive silver adhesive or any other suitable material) may have an electrical conductive property, but not limited thereto. The adhesive material CM may be in contact with the heat-dissipating element HS, the structural unit 124 and the electronic components. Through the adhesive material CM, heat generated by the electronic components can be conducted to the heat-dissipating element HS to be dissipated, but not limited thereto. In some embodiments, the heat-dissipating element HS includes, for example, a metal plate of a material including aluminum, copper, another metal material, or a combination of the foregoing. In some embodiments, the heat-dissipating element HS includes, for example, a non-metal heat-dissipating material.

In some embodiments, the structural unit 124 may have a good heat-conducting property. For example, it may include a metal material including, for example, aluminum, copper, another metal material, or a combination of the foregoing. The thermal conductivity coefficient of the structural unit 124 may be greater than or equal to 200 W/m·K and less than or equal to 600 W/m·K, but not limited thereto. The thermal conductivity coefficient of the structural unit 124 may be greater than or equal to 250 W/m·K and less than or equal to 550 W/m·K, or greater than or equal to 250 W/m·K and less than or equal to 500 W/m·K, or greater than or equal to 300 W/m·K and less than or equal to 450 w/m·k. In some embodiments, the thermal conductivity coefficient of the structural unit 124 may be greater than or equal to the thermal conductivity coefficient of the electronic component (e.g., the electronic component 1320, the electronic component 1322, the electronic component 1324 or the electronic component 1326). In some embodiments, the thermal conductivity coefficient of the structural unit 124 may be greater than or equal to the thermal conductivity coefficient of the encapsulation layer 126.

In other embodiments (not shown), the structural unit 124 may be disposed in the second region R2, or the structural unit 124 may be embedded in the circuit structure 104. The structural unit 124 has a first thermal expansion coefficient, one of the conductive layers of the circuit structure 104 has a second thermal expansion coefficient, and a ratio of the first thermal expansion coefficient to the second thermal expansion coefficient is greater than or equal to 0.1 and less than or equal to 0.8. Selection of the material of the structural unit 124 disposed in the second region R2, the design of the thermal expansion coefficients or the design of the dimensions (e.g., the maximum thickness) may refer to the above descriptions. There are a variety of ways to dispose the structural unit 124 in the second region R2. The structural unit 124 may be disposed in an opening of at least one of the insulating layers of the circuit structure 104. Details may be realized from the above descriptions.

Through the structural unit 124, the overall structure can be suppressed from warpage, or the thermal energy can be transferred to the heat-dissipating element HS, but not limited thereto. When the structural unit 124 is disposed in the first region R1, or when the structural unit 124 is disposed at a side (e.g., an upper side) of the circuit structure 104 in Direction V, or when the structural unit 124 is at least partially overlapped with the electronic components (e.g., the electronic component 1320, the electronic component 1322, the electronic component 1324 or the electronic component 1326) in Direction X (or Direction Y), a ratio of the first thermal expansion coefficient of the material of the structural unit 124 to the second thermal expansion coefficient of the material of one of the conductive layers of the circuit structure 104 (the first thermal expansion coefficient/the second thermal expansion coefficient) may be greater than or equal to 1.2 and less than or equal to 2, but not limited thereto. The ratio may also be greater than or equal to 1.3 and less than or equal to 1.9, or greater than or equal to 1.4 and less than or equal to 1.8.

When the ratio of the thermal expansion coefficients of the material of the structural unit 124 and the material of one of the conductive layers of the circuit structure 104 meets the above ranges, the warpage of the overall structure can be suppressed, so as to enhance yield or reliability of products. In some embodiments, when the structural unit 124 is disposed in the first region R1, the structural unit 124 may include passive components such as capacitors, resistors or inductors, but not limited thereto. In some embodiments, the passive components may be electrically connected to the circuit structure 104, but not limited thereto.

In some embodiments (not shown), when the structural unit 124 is disposed in the second region R2, or when the structural unit 124 is embedded in the circuit structure 104, or when the structural unit 124 is not overlapped with the electronic components in Direction X (or Direction Y), a ratio of the first thermal expansion coefficient of the material of the structural unit 124 to the second thermal expansion coefficient of the material of one of the conductive layers of the circuit structure 104 may be greater than or equal to 0.1 and less than or equal to 0.8, but not limited thereto. The above-mentioned ratio may also be greater than or equal to 0.15 and less than or equal to 0.75, or greater than or equal to 0.2 and less than or equal to 0.7.

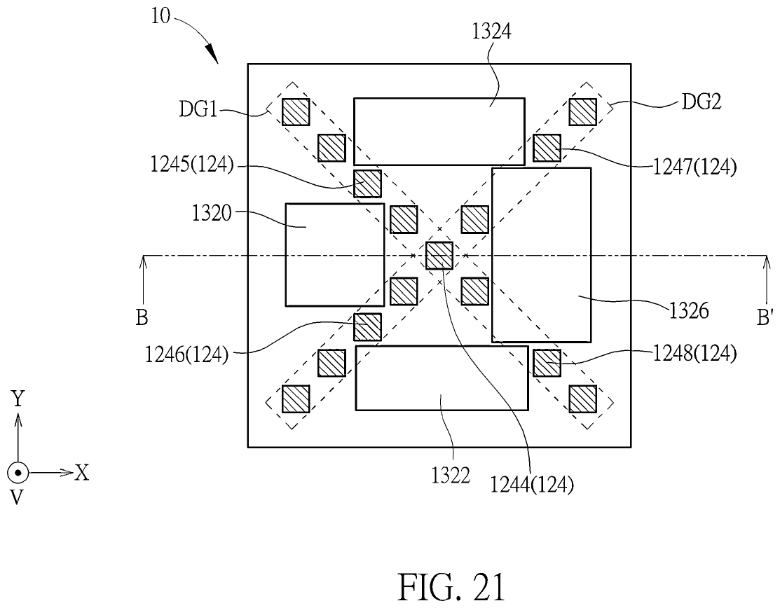

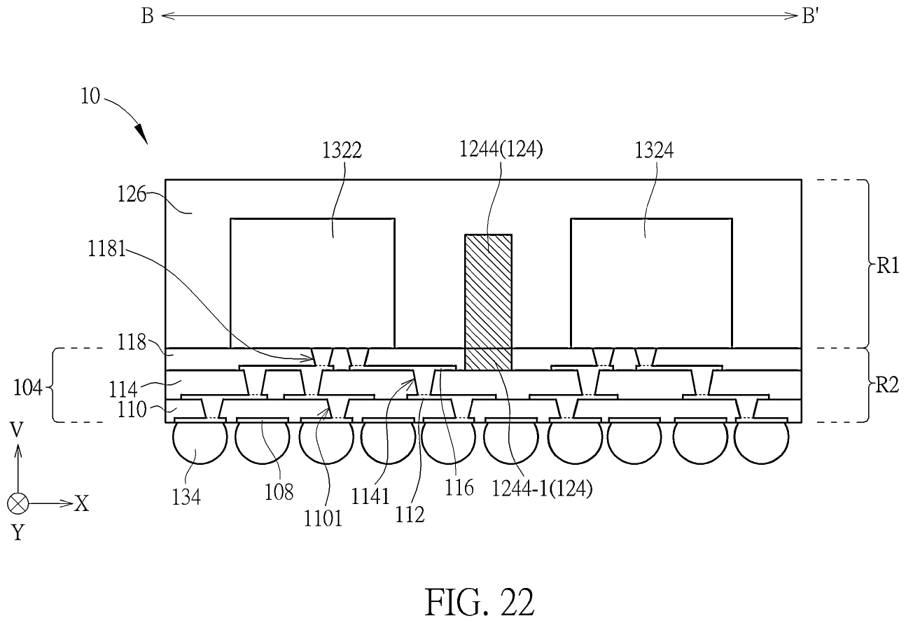

Please refer to FIG. 21 and FIG. 22. FIG. 21 is a top view schematically illustrating a structural unit and electronic components of an electronic device according to a tenth embodiment of the present disclosure. FIG. 22 is a cross-sectional view schematically illustrating the electronic device in the tenth embodiment. It differs from the ninth embodiment in that in the top view of the electronic device 10 in this embodiment, a portion of the structural unit 124 is disposed in the diagonal zone DG1, another portion of the structural unit 124 is disposed in the diagonal zone DG2, and at least a portion of the structural unit 124 is disposed between adjacent two of the electronic components (e.g., the electronic component 1320, the electronic component 1322, the electronic component 1324 and the electronic component 1326). For example, a portion 1244 of the structural unit 124 is disposed between the electronic component 1320 and the electronic component 1326 in Direction X. For example, the portion 1244 of the structural unit 124 is disposed between the electronic component 1322 and the electronic component 1324 in Direction Y. However, it is not limited thereto.

Furthermore, a portion 1245 of the structural unit 124 is disposed between the electronic component 1320 and the electronic component 1324 in Direction Y, and a portion 1246 of the structural unit 124 is disposed between the electronic component 1322 and the electronic component 1320 in Direction Y. A portion 1247 of the structural unit 124 is disposed between the electronic component 1324 and the electronic component 1326 in an oblique direction, and a portion 1248 of the structural unit 124 is disposed between the electronic component 1322 and the electronic component 1326 in another oblique direction, the oblique directions are parallel to neither Direction X nor Direction Y, and the oblique directions are perpendicular to Direction V. For example, an included angle between the oblique direction and Direction X may be about 45 degrees.

In some embodiments, in Direction X (or Direction Y), the maximum width of the portion 1244 may be less than or equal to the maximum width of the electronic component 1322 and/or the maximum width of the electronic component 1324, but not limited thereto. In some embodiments, in a cross-sectional view, the maximum thickness of the portion 1244 may be less than or equal to the maximum thickness of the electronic component 1322 and/or the maximum thickness of the electronic component 1324, but not limited thereto. In some embodiments (not shown), in a cross-sectional view, the maximum thickness of the portion 1244 may be greater than or equal to the maximum thickness of the electronic component 1322 and/or the maximum thickness of the electronic component 1324, but not limited thereto. In some embodiments, in a cross-sectional view, the maximum thickness of the electronic component 1322 and the maximum thickness of the electronic component 1324 may be the same or different. In some embodiments, in a top view, a plurality of portions (including the portion 1244) of the structural unit 124 are disposed between two adjacent electronic components. In some embodiments, a gap between the structural unit 124 and the electronic component (e.g., the electronic component 1320, the electronic component 1322, the electronic component 1324 or the electronic component 1326) in Direction X or Direction Y is greater than 0. In some embodiments (not shown), an electronic device illustrated in FIG. 22 may be analogous to that illustrated in FIG. 20, in which the structural unit 124 may be optionally electrically connected to the circuit structure 104, but not limited thereto.

The cross-sectional structure shown in FIG. 22 may correspond to the line B-B′ shown in FIG. 21. The structural unit 124 in this embodiment is disposed in the first region R1, and a portion (e.g., the portion 1244) of the structural unit 124 is disposed at a side (e.g., an upper side) of the circuit structure 104 in Direction V. Another portion (e.g., the portion 1244-1) of the structural unit 124 is disposed in the second region R2 in Direction V. In some embodiments, a portion (e.g., the portion 1244) of the structural unit 124 is at least partially overlapped with the electronic components (e.g., the electronic component 1320, the electronic component 1322, the electronic component 1324 and the electronic component 1326) in Direction X or Direction Y (i.e., a direction perpendicular to the top view direction (Direction V)), and the structural unit 124 is not overlapped with the electronic components (e.g., the electronic component 1320, the electronic component 1322, the electronic component 1324 and the electronic component 1326) in the top view direction (e.g., Direction V).

In an embodiment (not shown) of FIG. 22, the structural unit 124 (e.g., the portion 1244) may be selectively electrically connected to the circuit structure 104, but not limited thereto. Likewise, the encapsulation layer 126 may be disposed near the structural unit 124 and the electronic components (e.g., the electronic component 1320, the electronic component 1322, the electronic component 1324 and the electronic component 1326). The encapsulation layer 126 may surround at least the side surfaces of the structural unit 124 (e.g., the portion 1244) and the side surfaces of the electronic components (e.g., the electronic component 1320, the electronic component 1322, the electronic component 1324 and the electronic component 1326).

Although not shown in FIG. 22, similar to FIG. 20, the surface of the encapsulation layer 126 far away from the circuit structure 104 can optionally be substantially aligned with the surfaces of the electronic components (e.g., the electronic component 1320, the electronic component 1322, the electronic component 1324 and the electronic component 1326) or the surface of the structural unit 124.

Although not shown in FIG. 22, similar to FIG. 20, the heat-dissipating element HS may be selectively disposed on the encapsulation layer 126, the structural unit 124 and the electronic components. The adhesive material CM may be selectively disposed between the heat-dissipating element HS and the encapsulation layer 126, the structural unit 124, and the electronic components. The materials or the features of the above adhesive material CM and heat-dissipating element HS may refer to the above descriptions.

In some embodiments, the structural unit 124 (e.g., the portion 1244-1) may be disposed in the second region R2, or the structural unit 124 (e.g., the portion 1244-1) may be embedded into the circuit structure 104. Selection of the material of the structural unit 124 (e.g., the portion 1244-1) disposed in the second region R2, the design of the thermal expansion coefficients or the design of the dimensions (e.g., the maximum thickness) may refer to the above descriptions. The structural unit 124 (e.g., the portion 1244-1) has a first thermal expansion coefficient, one of the conductive layers of the circuit structure 104 has a second thermal expansion coefficient, and a ratio of the first thermal expansion coefficient to the second thermal expansion coefficient is greater than or equal to 0.1 and less than or equal to 0.8. There are a variety of ways to dispose the structural unit 124 (e.g., the portion 1244-1) in the second region R2. The structural unit 124 may be disposed in an opening of at least one of the insulating layers (e.g., the insulating layer 118) of the circuit structure 104. Details may be realized from the above descriptions.

Through the structural unit 124, the overall structure can be suppressed from warpage, or thermal energy can be transferred to the heat-dissipating element HS, but not limited thereto. The structural unit 124 has a first thermal expansion coefficient, one of the conductive layers of the circuit structure 104 has a second thermal expansion coefficient. When the structural unit 124 is disposed in the first region R1, or when the structural unit 124 is disposed above the circuit structure 104 in Direction V, or when the structural unit 124 is at least partially overlapped with the electronic components in a cross-sectional plane S, a ratio of the first thermal expansion coefficient of the material of the structural unit 124 to the second thermal expansion coefficient of the material of one of the conductive layers of the circuit structure 104 may be greater than or equal to 1.2 and less than or equal to 2, but not limited thereto. The ratio may also be greater than or equal to 1.3 and less than or equal to 1.9, or greater than or equal to 1.4 and less than or equal to 1.8.

When the ratio of the thermal expansion coefficients of the material of the structural unit 124 and the material of one of the conductive layers of the circuit structure 104 meets the above ranges, the warpage of the overall structure can be suppressed, so as to enhance yield or reliability of products. In some embodiments, when the structural unit 124 is disposed in the first region R1, the structural unit 124 may include passive components such as capacitors, resistors or inductors, but not limited thereto. In some embodiments, the passive components may be electrically connected to the circuit structure 104, but not limited thereto.

In some embodiments, when the structural unit 124 (e.g., the portion 1244-1) is disposed in the second region R2, or when the structural unit 124 (e.g., the portion 1244-1) is embedded in the circuit structure 104, or when the structural unit 124 is not overlapped with the electronic components in Direction X (or Direction Y), a ratio of the first thermal expansion coefficient of the material of the structural unit 124 to the second thermal expansion coefficient of the material of one of the conductive layers of the circuit structure 104 may be greater than or equal to 0.1 and less than or equal to 0.8, but not limited thereto. The above-mentioned ratio may also be greater than or equal to 0.15 and less than or equal to 0.75, or greater than or equal to 0.2 and less than or equal to 0.7.

To sum up, in the electronic device and the manufacturing method thereof of the present disclosure, the warpage of the whole structure is suppressed by the structural units, thereby effectively improving the yield or reliability of products. The structural unit can be removed during the manufacturing process or remain in the finished electronic device.

The above description refers to embodiments of the present disclosure, and it is not intended to limit the present disclosure. For those skilled in the art, the present disclosure can be modified or adjusted. As long as the different features between the embodiments do not conflict or depart from the spirit of the present disclosure, they can be rearranged or combined arbitrarily according to the designs. Any modification, equivalent substitution, improvement, etc. made within the spirit or principles of the present disclosure shall be included within the scope of the present disclosure.

What is claimed is:

1. A manufacturing method of an electronic device, comprising:
providing a carrier;
disposing a circuit structure on the carrier, which comprises alternately disposing a plurality of conductive layers and a plurality of insulating layers on the carrier, and electrically connecting adjacent two of the plurality of conductive layers via a plurality of through holes in one of the plurality of insulating layers; and
disposing a structural unit at a side of the circuit structure,
wherein the structural unit has a first thermal expansion coefficient, one of the plurality of conductive layers of the circuit structure has a second thermal expansion coefficient, and a ratio of the first thermal expansion coefficient to the second thermal expansion coefficient is greater than or equal to 1.2 and less than or equal to 2.

2. The manufacturing method of the electronic device according to claim 1, further comprising disposing a plurality of electronic components after the circuit structure is disposed, wherein the plurality of electronic components and the structural unit are at least partially overlapped in a direction parallel to a surface of the carrier, and the plurality of electronic components and the structural unit are not overlapped in another direction perpendicular to the surface of the carrier.

3. The manufacturing method of the electronic device according to claim 2, wherein in a top view, the structural unit surrounds the plurality of electronic components.

4. The manufacturing method of the electronic device according to claim 2, wherein the carrier comprises two diagonal zones, and at least a portion of the structural unit is disposed within the two diagonal zones.

5. The manufacturing method of the electronic device according to claim 1, further comprising disposing a plurality of electronic components before the circuit structure is disposed, wherein the plurality of electronic components and the structural unit are at least partially overlapped in a direction parallel to a surface of the carrier, and the plurality of electronic components and the structural unit are not overlapped in another direction perpendicular to the surface of the carrier.

6. The manufacturing method of the electronic device according to claim 1, wherein the first thermal expansion coefficient is greater than or equal to 20.4 ppm/° C. and less than or equal to 34 ppm/° C.

7. A manufacturing method of an electronic device, comprising:
providing a carrier; and
disposing a circuit structure and a structural unit on the carrier, wherein the structural unit is disposed in the circuit structure, and disposing the circuit structure comprises alternately disposing a plurality of conductive layers and a plurality of insulating layers on the carrier, and electrically connecting adjacent two of the plurality of conductive layers via a plurality of through holes in one of the plurality of insulating layers,
wherein the structural unit has a first thermal expansion coefficient, one of the plurality of conductive layers of the circuit structure has a second thermal expansion coefficient, and a ratio of the first thermal expansion coefficient to the second thermal expansion coefficient is greater than or equal to 0.1 and less than or equal to 0.8.

8. The manufacturing method of the electronic device according to claim 7, further comprising disposing a plurality of electronic components after the circuit structure is disposed, wherein the plurality of electronic components do not overlap the structural unit in a direction perpendicular to the surface of the carrier.

9. The manufacturing method of the electronic device according to claim 8, wherein in a top view, the structural unit surrounds the plurality of electronic components.

10. The manufacturing method of the electronic device according to claim 7, wherein the carrier comprises two diagonal zones, and at least a portion of the structural unit is disposed within the two diagonal zones.

11. The manufacturing method of the electronic device according to claim 7, further comprising disposing a plurality of electronic components before the circuit structure is disposed, wherein the plurality of electronic components do not overlap the structural unit in a direction perpendicular to the surface of the carrier.

12. The manufacturing method of the electronic device according to claim 7, wherein the first thermal expansion coefficient is greater than or equal to 1.7 ppm/° C. and less than or equal to 13.6 ppm/° C.

13. An electronic device, comprising:
a circuit structure comprising a plurality of conductive layers and at least one insulating layer, wherein the plurality of conductive layers are electrically interconnected via a plurality of through holes in the at least one insulating layer;
a plurality of electronic components electrically connected to the circuit structure and overlapping the circuit structure; and
a structural unit disposed adjacent to the plurality of electronic components, wherein in a top view of the electronic device, at least a portion of the structural unit is disposed between adjacent two of the plurality of electronic components.

14. The electronic device according to claim 13, wherein the plurality of electronic components and the structural unit are at least partially overlapped along a traverse sectional line in a cross-sectional view of the electronic device, and wherein the structural unit has a first thermal expansion coefficient, one of the plurality of conductive layers of the circuit structure has a second thermal expansion coefficient, and a ratio of the first thermal expansion coefficient to the second thermal expansion coefficient is greater than or equal to 1.2 and less than or equal to 2.

15. The electronic device according to claim 14, wherein the first thermal expansion coefficient is greater than or equal to 20.4 ppm/° C. and less than or equal to 34 ppm/° C.

16. The electronic device according to claim 14, wherein the structural unit comprises copper, aluminum, or copper alloy.

17. The electronic device according to claim 13, wherein the structural unit is embedded in the circuit structure, and wherein the structural unit has a first thermal expansion coefficient, one of the plurality of conductive layers of the circuit structure has a second thermal expansion coefficient, and a ratio of the first thermal expansion coefficient to the second thermal expansion coefficient is greater than or equal to 0.1 and less than or equal to 0.8.

18. The electronic device according to claim 17, wherein the first thermal expansion coefficient is greater than or equal to 1.7 ppm/° C. and less than or equal to 13.6 ppm/° C.

19. The electronic device according to claim 17, wherein the structural unit comprises glass, silicon nitride, or silicon oxide.

20. The electronic device according to claim 13, wherein the carrier comprises two diagonal zones, and at least a portion of the structural unit is disposed within the two diagonal zones.
